(19) United States
(12) Patent Application Publication
(10) Pub. No.: US 2026/0026205 A1
(43) Pub. Date: Jan. 22, 2026

(54) DISPLAY DEVICE, ELECTRONIC DEVICE USING THE SAME AND METHOD FOR FABRICATING THE SAME

(71) Applicant: Samsung Display Co., LTD., Yongin-si (KR)

(72) Inventors: Jong Hyun CHOUNG, Yongin-si (KR); Hyoung Sik KIM, Yongin-si (KR); Hyun Eok SHIN, Yongin-si (KR); Woo Jin CHO, Yongin-si (KR)

(21) Appl. No.: 19/182,879

(22) Filed: Apr. 18, 2025

(30) Foreign Application Priority Data
Jul. 17, 2024 (KR) 10-2024-0094675
Dec. 16, 2024 (KR) 10-2024-0187483

(51) Int. Cl. H10K 59/123; H10K 59/12

(52) U.S. Cl. CPC H10K 59/123; H10K 59/1201

(57) ABSTRACT

A display device includes a substrate including a semiconductor layer; a plurality of insulating layers defining a contact hole penetrating through the plurality of insulating layers and exposing the semiconductor layer, the plurality of insulating layers including a first insulating layer in contact with the semiconductor layer and a second insulating layer disposed in contact with the first insulating layer; and a conductive pattern covering the semiconductor layer and the insulating layers in a portion overlapping the contact hole. The semiconductor layer includes a recessed area that is recessed in a direction toward the substrate in the portion overlapping the contact hole, the first insulating layer and the second insulating layer include different materials from each other, and the recessed area of the semiconductor layer and the first insulating layer have a step-shaped level difference.

This application claims priority to Korean Patent Application No. 10-2024-0094675, filed on Jul. 17, 2024, and Korean Patent Application No. 10-2024-0187483, filed on Dec. 16, 2024, and all the benefits accruing therefrom under 35 U.S.C. § 119, the content of which in its entirety is herein incorporated by reference.

### BACKGROUND

### 1. Field

The disclosure relates to a display device, an electronic device using the same, and a method for fabricating the same.

### 2. Description of the Related Art

As an information society develops, the demand for a display device for displaying an image is increasing in various forms. For example, the display device is being applied to various electronic devices such as smartphones, digital cameras, laptop computers, navigation devices, and smart televisions. The display device may be a flat panel display device such as a liquid crystal display device, a field emission display device, or an organic light emitting display device. Among the flat panel display devices, the light emitting display device may include a light emitting element in which each of the pixels of a display panel may emit light by itself, thereby displaying an image without a backlight unit providing the light to the display panel.

### SUMMARY

Features of the disclosure provide a display device capable of providing a relatively high resolution image and a method for fabricating the display device.

Features of the disclosure provide a display device that solves contact defects of a conductive pattern in a portion overlapping a contact hole, an electronic device using the same, and a method for fabricating the display device.

However, features of the disclosure are not restricted to those set forth herein. The above and other features of the disclosure will become more apparent to one of ordinary skill in the art to which the disclosure pertains by referencing the detailed description of the disclosure given below.

Details of other embodiments are included in the detailed description and drawings.

In an embodiment, a display device includes: a substrate including a semiconductor layer; a plurality of insulating layers defining a contact hole which penetrates through the plurality of insulating layers and exposes the semiconductor layer, the plurality of insulating layers including a first insulating layer in contact with the semiconductor layer and a second insulating layer disposed in contact with the first insulating layer; and a conductive pattern covering the semiconductor layer and the plurality of insulating layers in a portion overlapping the contact hole. A recessed area that is recessed in a direction toward the substrate in the portion overlapping the contact hole is defined in the semiconductor layer, the first insulating layer and the second insulating layer include different materials from each other, and the recessed area of the semiconductor layer and the first insulating layer have a step-shaped level difference.

In an embodiment, the first insulating layer may protrude further in a direction toward the contact hole than the second insulating layer, and the recessed area of the semiconductor layer, the first insulating layer, and the second insulating layer have a step-shaped level difference.

In an embodiment, the first insulating layer may define a first opening in the portion overlapping the contact hole, the second insulating layer defines a second opening in the portion overlapping the contact hole, and a width of the first opening and a width of the second opening may be different from each other.

In an embodiment, the width of the first opening may be smaller than the width of the second opening.

In an embodiment, a difference between the width of the first opening and the width of the second opening may be 10 angstroms or more and 300 angstroms or less.

In an embodiment, an aspect ratio of the contact hole may be defined as a value obtained by dividing a depth of the contact hole by a width of the contact hole, and the aspect ratio of the contact hole may be 0.6 or greater.

In an embodiment, the depth of the contact hole may be 1.2 micrometers or more, and the width of the contact hole may be 2.0 micrometers or less.

In an embodiment, the recessed area of the semiconductor layer may do not overlap the plurality of insulating layers in a direction perpendicular to the substrate.

In an embodiment, a width of the recessed area of the semiconductor layer in a direction parallel to the substrate may be smaller than a width of the contact hole.

In an embodiment, the semiconductor layer may include polysilicon.

In an embodiment, a side surface of the first insulating layer facing the contact hole may be disposed on the same line as a side surface of the second insulating layer facing the contact hole.

In an embodiment, the conductive pattern may contact and covers the recessed area of the semiconductor layer, the first insulating layer, and the second insulating layer in the portion overlapping the contact hole.

In an embodiment of the disclosure, a method for fabricating a display device includes: forming a plurality of insulating layers on a substrate including a semiconductor layer; removing a portion of the plurality of insulating layers by performing a dry etching process; defining a contact hole by performing a dry cleaning process; and forming a conductive pattern in a portion overlapping the contact hole. The plurality of insulating layers include a first insulating layer in contact with the semiconductor layer and a second insulating layer in contact with the first insulating layer and including a different material from the first insulating layer.

In an embodiment, in the removing the portion of the plurality of insulating layers by performing the dry etching process, the semiconductor layer may define a recessed area that is recessed in a direction toward the substrate.

In an embodiment, in the defining the contact hole by performing the dry cleaning process, the recessed area of the semiconductor layer, the first insulating layer, and the second insulating layer may include a step-shaped level difference.

In an embodiment of the disclosure, an electronic device includes: a display device including a substrate including a semiconductor layer; a display device accommodating portion in which the display device is accommodated; and an optical member enlarging a display image of the display device or converting a light path. The display device includes: a plurality of insulating layers defining a contact hole which penetrates through the plurality of insulating layers and exposes the semiconductor layer, the plurality of insulating layers including a first insulating layer in contact with the semiconductor layer and a second insulating layer disposed in contact with the first insulating layer; and a conductive pattern covering the semiconductor layer and the plurality of insulating layers in a portion overlapping the contact hole, the semiconductor layer includes a recessed area that is recessed in a direction toward the substrate in the portion overlapping the contact hole, the first insulating layer and the second insulating layer include different materials from each other, and the recessed area of the semiconductor layer and the first insulating layer have a step-shaped level difference.

In an embodiment, the first insulating layer may protrude further in a direction toward the contact hole than the second insulating layer, and the recessed area of the semiconductor layer, the first insulating layer, and the second insulating layer have a step-shaped level difference.

In an embodiment, the first insulating layer may define a first opening in the portion overlapping the contact hole, the second insulating layer defines a second opening in the portion overlapping the contact hole, and the width of the first opening is smaller than the width of the second opening.

In an embodiment, a difference between the width of the first opening and the width of the second opening may be 10 angstroms or more and 300 angstroms or less.

In an embodiment, an aspect ratio of the contact hole may be defined as a value obtained by dividing a depth of the contact hole by a width of the contact hole, and the aspect ratio of the contact hole may be 0.6 or greater.

According to the display device, the electronic device using the same, and the method for fabricating the display device in the embodiments, a high-resolution image may be provided, and the contact defects of the conductive pattern in the portion overlapping the contact hole may be solved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a head mounted electronic device;

FIG. 2 is an exploded perspective view illustrating an embodiment of the head mounted electronic device of FIG. 1;

FIG. 3 is a perspective view illustrating an embodiment of a head mounted electronic device;

FIG. 4 is a perspective view illustrating an embodiment of a display device;

FIG. 5 is a cross-sectional view illustrating an embodiment of the display device;

FIG. 6 is a plan view illustrating an embodiment of a display layer of the display device;

FIG. 7 is a cross-sectional view illustrating an embodiment of the display layer taken along line X-X′ of FIG. 6;

FIG. 8 is an enlarged cross-sectional view of area ‘A1’ of FIG. 7;

FIG. 9 is an enlarged cross-sectional view of a lower area of a first contact hole of FIG. 8 according to a comparative example;

FIG. 10 is an enlarged cross-sectional view of another embodiment of area ‘A1’ of FIG. 7;

FIG. 11 is an enlarged cross-sectional view of another embodiment of area ‘A1’ of FIG. 7;

FIG. 12 is an enlarged cross-sectional view of area ‘A3’ of FIG. 7;

FIG. 13 is a flowchart illustrating a process of fabricating a first conductive pattern and a second conductive pattern in FIG. 7;

FIG. 14 is a cross-sectional view illustrating operation S100 of FIG. 13;

FIGS. 15 and 16 are cross-sectional views illustrating operation S200 of FIG. 13;

FIG. 17 is a cross-sectional view illustrating operation S300 of FIG. 13;

FIG. 18 is a graph illustrating an etch rate change of an inorganic material according to temperature change in a dry cleaning process;

FIG. 19 is a cross-sectional view illustrating operation S300 of FIG. 13;

FIGS. 20 and 21 are cross-sectional views illustrating operation S400 of FIG. 13;

FIG. 22 is a block diagram of an embodiment of an electronic device; and

FIG. 23 illustrates schematic diagrams of electronic devices according to various embodiments.

### DETAILED DESCRIPTION

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it may be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

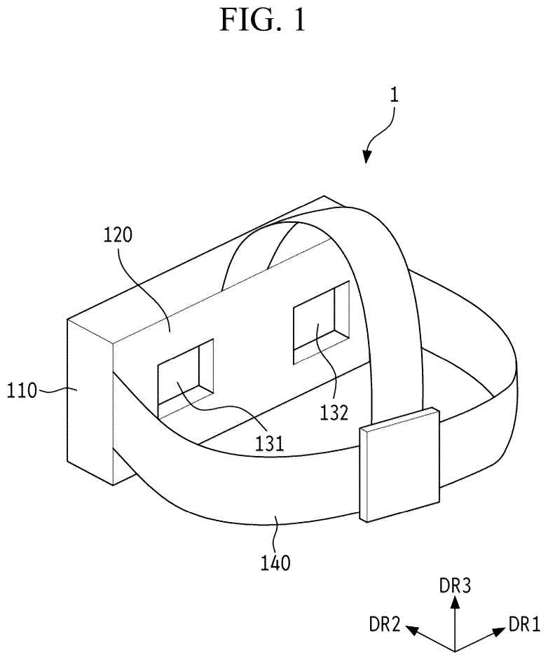

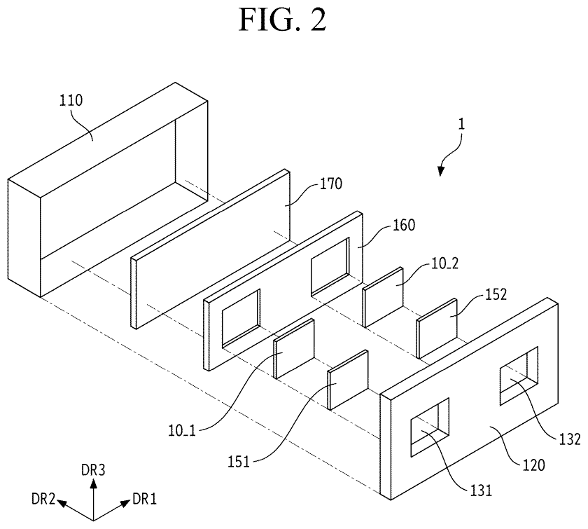

FIG. 1 is a perspective view illustrating an embodiment of a head mounted electronic device. FIG. 2 is an exploded perspective view illustrating an embodiment of the head mounted electronic device of FIG. 1.

Referring to FIGS. 1 and 2, a head mounted electronic device 1 in an embodiment includes a display device accommodating portion 110, an accommodating portion cover 120, a first eyepiece 131, a second eyepiece 132, a head mounting band 140, a first display device 10_1, a second display device 10_2, a middle frame 160, a first optical member 151, a second optical member 152, a control circuit board 170, and a connector.

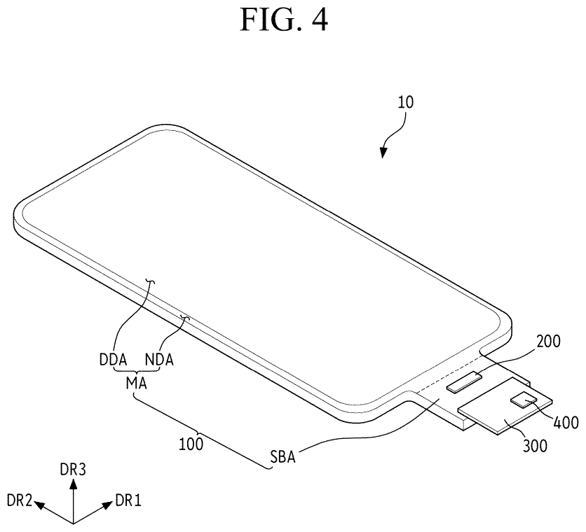

The first display device 10_1 provides an image to a user's left eye, and the second display device 10_2 provides an image to a user's right eye. Each of the first display device 10_1 and the second display device 10_2 is substantially the same as a display device 10 described with reference to FIG. 4. Accordingly, descriptions of the first display device 10_1 and the second display device 10_2 will be replaced with descriptions with reference to FIG. 4.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device accommodating portion 110. The control circuit board 170 may be connected to the first display device 10_1 and the second display device 10_2 through a connector. The control circuit board 170 may convert an image source input from the outside into digital video data, and may transmit the digital video data to the first display device 10_1 and the second display device 10_2 through the connector.

The control circuit board 170 may transmit digital video data corresponding to a left eye image optimized for the user's left eye to the first display device 10_1, and may transmit digital video data corresponding to a right eye image optimized for the user's right eye to the second display device 10_2. In an alternative embodiment, the control circuit board 170 may transmit the same digital video data to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 is disposed to cover one opened surface of the display device accommodating portion 110. The accommodating portion cover 120 may include a first eyepiece 131 where the user's left eye is disposed and a second eyepiece 132 where the user's right eye is disposed. It is illustrated in FIGS. 1 and 2 that the first eyepiece 131 and the second eyepiece 132 are separately disposed, but the embodiment of the specification is not limited thereto. The first eyepiece 131 and the second eyepiece 132 may be integrated into one.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

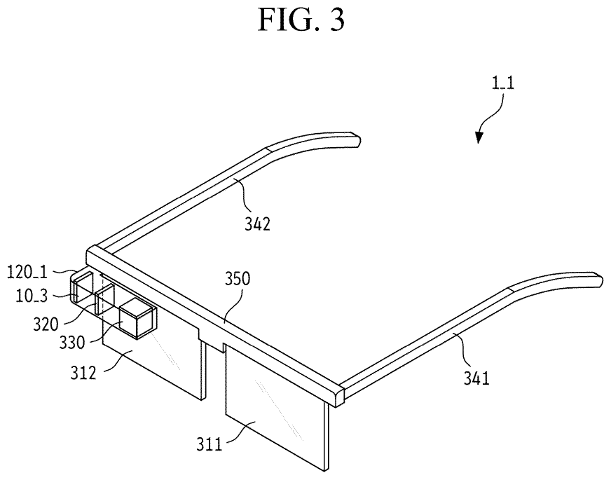

The head mounting band 140 serves to fix the display device accommodating portion 110 to a user's head so that the first eyepiece 131 and the second eyepiece 132 of the accommodating portion cover 120 are disposed on the user's left and right eyes, respectively. When the display device accommodating portion 110 is implemented in a lightweight and relatively small size, the head mounted electronic device 1 may include eyeglass frames as illustrated in FIG. 3 instead of the head mounting band 140.

In addition, the head mounted electronic device 1 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (“HDMI”) terminal, and the wireless communication module may be a 5G communication module, a 4G communication module, a Wi-Fi module, or a Bluetooth© module.

FIG. 3 is a perspective view illustrating an embodiment of a head mounted electronic device.

Referring to FIG. 3, a head mounted electronic device 1_1 in an embodiment may be a glasses-type display device in which a display device accommodating portion 120_1 is implemented in a lightweight and relatively small size. The head mounted electronic device 1_1 in an embodiment may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 is substantially the same as the display device 10 described with reference to FIG. 4.

The display device accommodating portion 1201 may include the display device 10_3, the optical member 320, and the light path conversion member 330. As an image displayed on the display device 10_3 is magnified by the optical member 320 and a light path thereof is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is disposed at a right distal end of the support frame 350, but the embodiment of the specification is not limited thereto. In an embodiment, the display device accommodating portion 120_1 may be disposed at a left distal end of the support frame 350, and in this case, the image of the display device 10_3 may be provided to the user's left eye, for example. In an alternative embodiment, the display device accommodating portions 120_1 may be disposed at both the left and right distal ends of the support frame 350. In this case, the user may view the image displayed on the display device 10_3 through both the user's left and right eyes.

FIG. 4 is a perspective view illustrating an embodiment of a display device.

Referring to FIG. 4, a display device 10 may be applied to portable electronic devices such as a mobile phone, a smartphone, a tablet personal computer (“PC”), a mobile communication terminal, an electronic notebook, an electronic book, a portable multimedia player (“PMP”), navigation, and an ultra mobile PC (“UMPC”). In an embodiment, the display device 10 may be applied to a display unit of a television, a laptop computer, a monitor, a billboard, or the Internet of Things (“IoT”), for example. In another embodiment, the display device 10 may be applied to a wearable device such as a smart watch, a watch phone, a glasses-type display, and a head disposed (e.g., mounted) display (“HMD”).

The display device 10 may be formed in a planar shape similar to a quadrangle. In an embodiment, the display device 10 may have a planar shape similar to a quadrangle having a short side in a first direction DR1 and a long side in a second direction DR2, for example. A corner where the short side in the first direction DR1 and the long side in the second direction DR2 meet may be rounded to have a predetermined curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DDA including pixels displaying an image, and a non-display area NDA disposed around the display area DDA.

The display area DDA may emit light from a plurality of light emitting areas or a plurality of openings to be described later. In an embodiment, the display panel 100 may include a pixel circuit including switching elements, a pixel defining layer defining the light emitting areas or the openings, and a self-light emitting element, for example. In an embodiment, the self-light emitting element may include, but is not limited to, at least one of an organic light emitting diode (“LED”) including an organic light emitting layer, a quantum dot LED including a quantum dot light emitting layer, an inorganic LED including an inorganic semiconductor, and a micro LED, for example. In the following drawings, it is illustrated that the self-light emitting element is an organic light emitting diode.

The non-display area NDA may be an area outside the display area DDA. The non-display area NDA may be defined as an edge area of the main area MA of the display panel 100.

The sub-area SBA may be an area extending from one side of the main area MA. The sub-area SBA may include a flexible material that may be bent, folded, rolled, or the like. In an embodiment, when the sub-area SBA is bent, the sub-area SBA may overlap the main area MA in a thickness direction (e.g., a third direction DR3), for example. The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may be formed as an integrated circuit (“IC”) and disposed (e.g., mounted) on the display panel 100 by a chip on glass (“COG”) method, a chip on plastic (“COP”) method, or an ultrasonic bonding method. In an embodiment, the display driver 200 may be disposed in the sub-area SBA, and may overlap the main area MA in the thickness direction by bending of the sub-area SBA, for example. In another embodiment, the display driver 200 may be disposed (e.g., mounted) on the circuit board 300.

The circuit board 300 may be attached onto the pad portion of the display panel 100 using an anisotropic conductive film (“ACF”). The circuit board 300 may be a flexible film such as a flexible printed circuit board, a printed circuit board, or a chip on film.

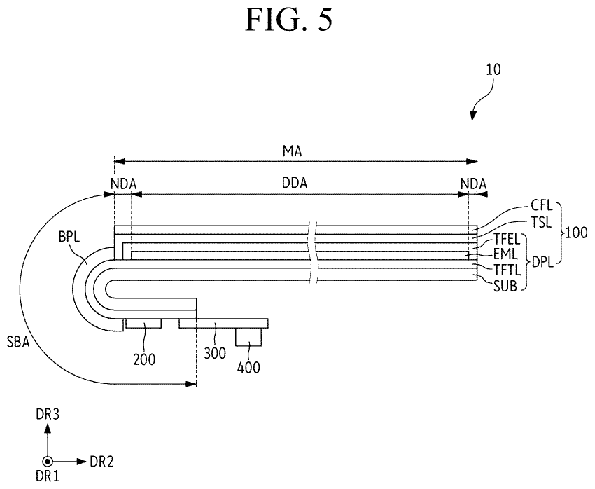

The touch driver 400 may be disposed (e.g., mounted) on the circuit board 300. The touch driver 400 may be connected to a touch sensor layer (TSL in FIG. 5) for sensing and driving a touch of the display device 10.

FIG. 5 is a cross-sectional view illustrating an embodiment of the display device.

Referring to FIG. 5, the display panel 100 may include a display layer DPL, a touch sensor layer TSL, and a color filter layer CFL. The display layer DPL may include a substrate SUB, a transistor layer TFTL, a display element layer EML, and an encapsulation layer TFEL.

The substrate SUB may be a base substrate or a base member. The substrate SUB may be a flexible substrate that may be bent, folded, rolled, or the like. In an embodiment, the substrate SUB may include a polymer resin such as polyimide (“PI”), for example, but is not limited thereto. In another embodiment, the substrate SUB may include a glass material or a metal material.

The transistor layer TFTL may be disposed on the substrate SUB. The transistor layer TFTL may be disposed in a portion overlapping the display area DDA, the non-display area NDA, and the sub-area SBA.

The display element layer EML may be disposed on the transistor layer TFTL. The display element layer EML may be disposed in a portion overlapping the display area DDA. The display element layer EML may include, but is not limited to, at least one of an organic light emitting diode (“LED”) including an organic light emitting layer, a quantum dot LED including a quantum dot light emitting layer, an inorganic LED including an inorganic semiconductor, and a micro LED.

The encapsulation layer TFEL may be disposed on the display element layer EML. The encapsulation layer TFEL may be disposed in a portion overlapping the display area DDA and the non-display area NDA. The encapsulation layer TFEL may cover an upper surface and side surfaces of the display element layer EML, and may protect the display element layer EML from oxygen and moisture from the outside. The encapsulation layer TFEL may include at least one inorganic film and at least one organic film for encapsulating the display element layer EML.

The touch sensor layer TSL may be disposed on the encapsulation layer TFEL. The touch sensor layer TSL may be disposed in a portion overlapping the display area DDA and the non-display area NDA. The touch sensor layer TSL may sense a user's touch in a mutual capacitance method or a self-capacitance method. In some embodiments, the touch sensor layer TSL may be omitted.

The color filter layer CFL may be disposed on the touch sensor layer TSL. The color filter layer CFL may be disposed in a portion overlapping the display area DDA and the non-display area NDA. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the touch sensor layer TSL, a separate substrate for the color filter layer CFL may not be desired in the display device 10. Therefore, the display device 10 may have a relatively small thickness. In some embodiments, the color filter layer CFL may also be omitted.

As illustrated in FIG. 5, a portion of the display panel 100 overlapping the sub-area SBA may be bent. When a portion of the display panel 100 is bent, the display driver 200, circuit board 300, and the touch driver 400 may overlap the main area MA in the third direction DR3.

When a portion of the display panel 100 is bent, a bending protection layer BPL may protect a lower structure disposed to overlap the sub-area SBA from bending stress.

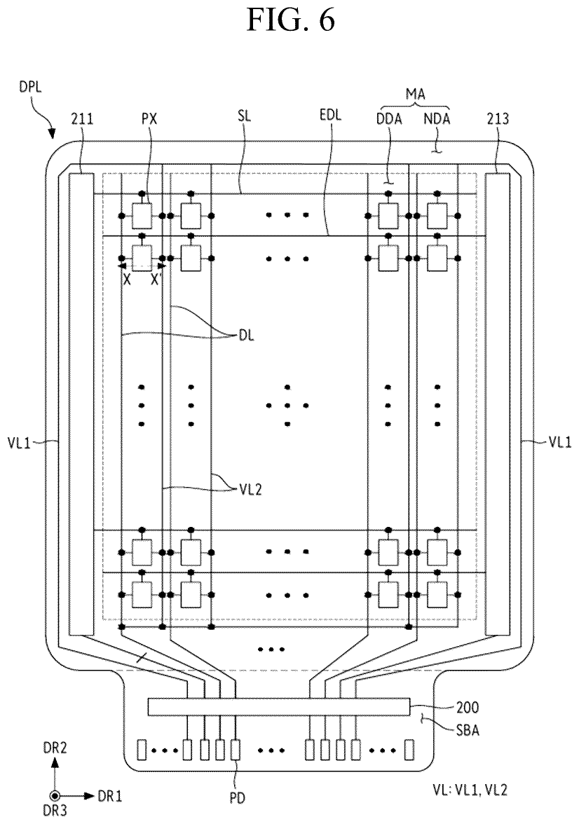

FIG. 6 is a plan view illustrating an embodiment of a display layer of the display device.

Referring to FIG. 6, the display layer DPL may include a plurality of pixels PX in a portion overlapping the display area DDA, and a plurality of power lines VL, a plurality of scan lines SL, a plurality of emission control lines EDL, and a plurality of data lines DL that are connected to the plurality of pixels PX.

Each of the plurality of scan lines SL may extend in the first direction DR1 and may be spaced apart from each other in the second direction DR2 intersecting the first direction DR1. The scan lines SL may be arranged along the second direction DR2. The scan lines SL may sequentially supply a scan signal to the plurality of pixels PX.

Each of the emission control lines EDL may extend in the first direction DR1 and may be spaced apart from each other in the second direction DR2. The emission control lines EDL may be arranged along the second direction DR2. The emission control lines EDL may sequentially supply a light emitting signal to the plurality of pixels PX.

The data lines DL may extend in the second direction DR2 and may be spaced apart from each other in the first direction DR1. The data lines DL may be arranged along the first direction DR1. The data lines DL may supply a data voltage to the plurality of pixels PX. The data voltage may determine luminance of each of the plurality of pixels PX.

The power line VL may include a main power line VL1 and a sub-power line VL2. At least one of a first power voltage (high potential voltage) or a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA. The non-display area NDA may include a scan driver 211 and an emission control driver 213.

The scan driver 211 may be disposed on the outside of one side of the display area DDA or on one side of the non-display area NDA. The scan driver 211 may include a plurality of driving transistors that generate gate signals based on a gate control signal.

The emission control driver 213 may be disposed on the outside of an opposite side of the display area DDA or on an opposite side of the non-display area NDA. The emission control driver 213 may include a plurality of emission control transistors that generate light emitting signals based on an emission control signal.

The display layer DPL included in an embodiment may include a display driver 200 and a plurality of pad electrodes PD in a portion overlapping the sub-area SBA. The plurality of pad electrodes PD may be spaced apart from each other in the first direction DR1, and each pad electrode PD may be connected to each different line.

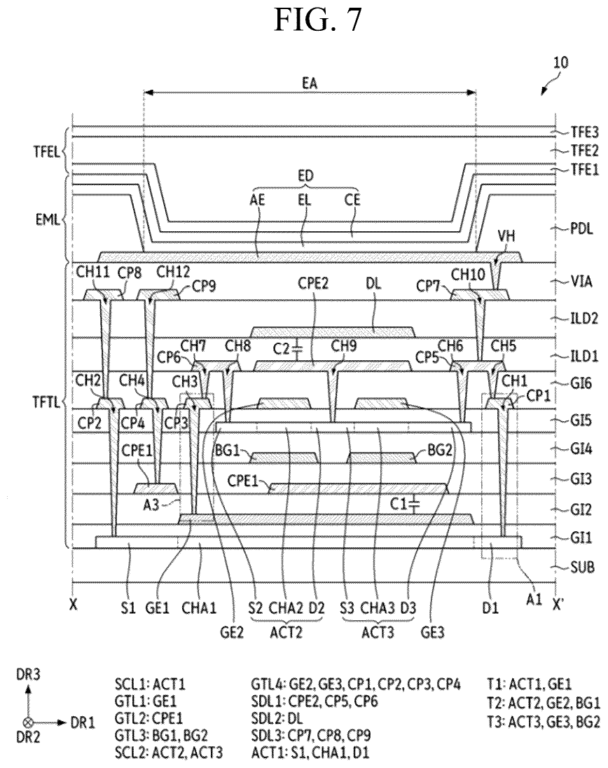

FIG. 7 is a cross-sectional view illustrating an embodiment of the display layer taken along line X-X′ of FIG. 6. FIG. 7 illustrates a schematic cross-sectional view of the substrate SUB, the transistor layer TFTL, the display element layer EML, and the encapsulation layer TFEL included in the display layer DPL.

Referring to FIG. 7 in addition to FIGS. 1 to 6, the transistor layer TFTL may be disposed on the substrate SUB. The transistor layer TFTL may include a plurality of semiconductor layers, a plurality of conductive layers, and a plurality of insulating layers.

As the display device 10 in an embodiment is applied to the high-resolution electronic device 1, the semiconductor layers and/or the conductive layers included in the transistor layer TFTL may be disposed while securing an appropriate separation distance within a narrow area. The plurality of semiconductor layers and/or conductive layers may be formed by being stacked in the third direction DR3 with the plurality of insulating layers interposed therebetween.

In an embodiment, the transistor layer TFTL may include a first semiconductor layer SCL1, a first insulating layer GI1, a first conductive layer GTL1, a second insulating layer GI2, a second conductive layer GTL2, a third insulating layer GI3, a third conductive layer GTL3, a fourth insulating layer GI4, a second semiconductor layer SCL2, a fifth insulating layer GI5, a fourth conductive layer GTL4, a sixth insulating layer GI6, a fifth conductive layer SDL1, a first interlayer insulating layer ILD1, a sixth conductive layer SDL2, a second interlayer insulating layer ILD2, a seventh conductive layer SDL3, and a via layer VIA.

The first semiconductor layer SCL1 may be disposed on the substrate SUB. The first semiconductor layer SCL1 may include a first active layer ACT1 included in a first transistor T1 of the pixel PX.

The first active layer ACT1 may include a first channel region CHA1, a first source region S1, and a first drain region D1. The first channel region CHA1 may overlap a first gate electrode GE1 in the third direction DR3. The first channel region CHA1 may form a channel to correspond to a voltage applied to the first gate electrode GE1.

The first source region S1 and the first drain region D1 may be disposed on opposite sides of the first channel region CHA1. The first source region S1 and the first drain region D1 may have higher conductivity than that of the first channel region CHA1. In an embodiment, a carrier concentration of the first source region S1 and the first drain region D1 may be higher than a carrier concentration of the first channel region CHA1.

The first insulating layer GI1 may be disposed on the substrate SUB and the first semiconductor layer SCL1. The first insulating layer GI1 may cover an entirety of the first semiconductor layer SCL1.

The first conductive layer GTL1 may be disposed on the first insulating layer GI1. The first conductive layer GTL1 may include a conductive material. In an embodiment, the first conductive layer GTL1 may include at least one of molybdenum (Mo), aluminum (Al), chromium (Cr), gold (Au), silver (Ag), titanium (Ti), nickel (Ni), neodymium (Nd), copper (Cu), and other metals, any alloys thereof, or other conductive materials.

The first conductive layer GTL1 may include a first gate electrode GE1 included in a first transistor T1 of the pixel PX.

The first gate electrode GE1 may overlap the first channel region CHA1 of the first active layer ACT1 and a first capacitor electrode CPE1 in the third direction DR3. The first gate electrode GE1 may be spaced apart from the first channel region CHA1 of the first active layer ACT1 and the first capacitor electrode CPE1.

The second insulating layer GI2 may be disposed on the first insulating layer GI1 and the first conductive layer GTL1. The second insulating layer GI2 may cover an entirety of the first conductive layer GTL1.

The second conductive layer GTL2 may be disposed on the second insulating layer GI2. The second conductive layer GTL2 may include a conductive material. In embodiments, the conductive material are omitted.

The second conductive layer GTL2 may include a first capacitor electrode CPE1. The first capacitor electrode CPE1 illustrated as being separated into two patterns in FIG. 7 may be one electrode that is connected in a plan view.

A first capacitor C1 may be formed between the first gate electrode GE1 and the first capacitor electrode CPE1. The first gate electrode GE1 and the first capacitor electrode CPE1 may form a first electrode and a second electrode of the first capacitor C1, respectively.

The third insulating layer GI3 may be disposed on the second insulating layer GI2 and the second conductive layer GTL2. The third insulating layer GI3 may cover an entirety of the second conductive layer GTL2.

The third conductive layer GTL3 may be disposed on the third insulating layer GI3. The third conductive layer GTL3 may include a conductive material. In embodiments, the conductive material are omitted.

The third conductive layer GTL3 may include a first lower gate electrode BGI and a second lower gate electrode BG2. The first lower gate electrode BGI may overlap a second active layer ACT2 included in a second transistor T2 in the third direction DR3, and the second lower gate electrode BG2 may overlap a third active layer ACT3 included in a third transistor T3 in the third direction DR3.

The fourth insulating layer GI4 may be disposed on the third insulating layer GI3 and the third conductive layer GTL3. The fourth insulating layer GI4 may cover an entirety of the third conductive layer GTL3.

The second semiconductor layer SCL2 may be disposed on the fourth insulating layer GI4. The second semiconductor layer SCL2 may include a second active layer ACT2 included in a second transistor T2 and a third active layer ACT3 included in a third transistor T3.

The second semiconductor layer SCL2 may include a semiconductor material (e.g., polysilicon, amorphous silicon, an oxide semiconductor, or other semiconductor materials).

In an embodiment, the second active layer ACT2 and the third active layer ACT3 may be unitary. In an embodiment, a second drain region D2 and a third source region S3 may be one integral region.

The second active layer ACT2 may include a second channel region CHA2, a second source region S2, and a second drain region D2. The second channel region CHA2 may overlap a second gate electrode GE2 included in the second transistor T2 in the third direction DR3. The second channel region CHA2 may form a channel to correspond to a voltage applied to the second gate electrode GE2. The second source region S2 and the second drain region D2 may be disposed on opposite sides of the second channel region CHA2. The second source region S2 and the second drain region D2 may have higher conductivity than the second channel region CHA2.

The third active layer ACT3 may include a third channel region CHA3, a third source region S3, and a third drain region D3. The third channel region CHA3 may overlap a third gate electrode GE3 included in the third transistor T3 in the third direction DR3. The third channel region CHA3 may form a channel to correspond to a voltage applied to the third gate electrode GE3. The third source region S3 and the third drain region D3 may be disposed on opposite sides of the third channel region CHA3. The third source region S3 and the third drain region D3 may have higher conductivity than that of the third channel region CHA3.

In an embodiment, the second source region S2 may be electrically connected to the first gate electrode GE1 through a sixth conductive pattern CP6 and a third conductive pattern CP3.

The second drain region D2 may be integral with the third source region S3. The second drain region D2 and the third source region S3 may be electrically connected to the second capacitor electrode CPE2.

The third drain region D3 may be connected to the first drain region D1 of the first active layer ACT1 through a fifth conductive pattern CP5 and a first conductive pattern CP1. In addition, the third drain region D3 may be electrically connected to an anode electrode AE of a light emitting element ED through the fifth conductive pattern CP5 and a seventh conductive pattern CP7.

The fifth insulating layer GI5 may be disposed on the fourth insulating layer GI4 and the second semiconductor layer SCL2. The fifth insulating layer GI5 may cover an entirety of the second semiconductor layer SCL2.

The fourth conductive layer GTL4 may be disposed on the fifth insulating layer GI5. The fourth conductive layer GTL4 may include a conductive material. In embodiments, the conductive material are omitted.

In an embodiment, the fourth conductive layer GTL4 may include a first conductive pattern CP1, a second conductive pattern CP2, a third conductive pattern CP3, a fourth conductive pattern CP4, a second gate electrode GE2, and a third gate electrode GE3. The description of the second gate electrode GE2 and the third gate electrode GE3 is omitted.

The first conductive pattern CP1 may be electrically connected to the first drain region D1 of the first active layer ACT1 by penetrating through a plurality of insulating layers disposed between the first semiconductor layer SCL1 and the fourth conductive layer GTL4. Specifically, the first conductive pattern CP1 may be electrically connected to the first drain region D1 through a first contact hole CH1 that collectively penetrates through the first insulating layer GI1, the second insulating layer GI2, the third insulating layer GI3, the fourth insulating layer GI4, and the fifth insulating layer GI5. In an embodiment, the first conductive pattern CP1 may be a drain electrode of the first transistor T1 and may also be considered as a configuration included in the first transistor T1.

The second conductive pattern CP2 may be electrically connected to the first source region S1 of the first active layer ACT1 by penetrating through a plurality of insulating layers disposed between the first semiconductor layer SCL1 and the fourth conductive layer GTL4. Specifically, the second conductive pattern CP2 may be electrically connected to the first source region S1 through a second contact hole CH2 that collectively penetrates through the first insulating layer GI1, the second insulating layer GI2, the third insulating layer GI3, the fourth insulating layer GI4, and the fifth insulating layer GI5. In an embodiment, the second conductive pattern CP2 may be a source electrode of the first transistor T1 and may also be considered as a configuration included in the first transistor T1.

The third conductive pattern CP3 may be electrically connected to the first gate electrode GE1 by penetrating through a plurality of insulating layers disposed between the first conductive layer GTL1 and the fourth conductive layer GTL4. Specifically, the third conductive pattern CP3 may be electrically connected to the first gate electrode GE1 through a third contact hole CH3 defined in the second insulating layer GI2, the third insulating layer GI3, the fourth insulating layer GI4, and the fifth insulating layer GI5.

The fourth conductive pattern CP4 may be electrically connected to the first capacitor electrode CPE1 by penetrating through a plurality of insulating layers disposed between the second conductive layer GTL2 and the fourth conductive layer GTL4. Specifically, the fourth conductive pattern CP4 may be electrically connected to the first capacitor electrode CPE1 through a fourth contact hole CH4 defined in the third insulating layer GI3, the fourth insulating layer GI4, and the fifth insulating layer GI5.

A plurality of contact holes defined in the transistor layer TFTL in an embodiment may be formed to penetrate through the plurality of insulating layers. Each contact hole may have a depth corresponding to a thickness of the plurality of insulating layers. In other words, the plurality of contact holes defined in the transistor layer TFTL in an embodiment may have a deep and narrow width.

In an embodiment, the plurality of contact holes (e.g., contact holes defined to penetrate through at least three or more insulating layers) defined in the transistor layer TFTL in an embodiment may have an aspect ratio (“AR”) of 0.6 or greater, for example. The aspect ratio (“AR”) may mean a value obtained by dividing the depth of the contact hole by the width of the contact hole (e.g., depth of the contact hole/width of the contact hole). In an embodiment, the width of each of the plurality of contact holes defined in the display device 10 in an embodiment may be 2.0 micrometers or less, and the depth of each of the plurality of contact holes may be 1.2 micrometers or more. The range of the aspect ratio (“AR”), width, and depth of the contact hole described above may be key indicators of the transistor layer TFTL designed for the high-resolution display device.

In an embodiment, the first to fourth contact holes CH1, CH2, CH3, and CH4 may be defined by penetrating through at least three or more insulating layers, and accordingly, the first to fourth contact holes CH1, CH2, CH3, and CH4 may have the range of the aspect ratio (“AR”), width, and depth of the contact holes described above. The redundant descriptions will be omitted.

The sixth insulating layer GI6 may be disposed on the fifth insulating layer GI5 and the fourth conductive layer GTL4. The sixth insulating layer GI6 may cover an entirety of the fourth conductive layer GTL4.

The sixth insulating layer GI6 may include an inorganic insulating material. In an embodiment, the sixth insulating layer GI6 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The fifth conductive layer SDL1 may be disposed on the sixth insulating layer GI6. The fifth conductive layer SDL1 may include a conductive material. In embodiments, the conductive material are omitted.

The fifth conductive layer SDL1 may include a fifth conductive pattern CP5, a sixth conductive pattern CP6, and a second capacitor electrode CPE2.

The fifth conductive pattern CP5 may be electrically connected to the first conductive pattern CP1 by penetrating through an insulating layer disposed between the fourth conductive layer GTL4 and the fifth conductive layer SDL1. Specifically, the fifth conductive pattern CP5 may be electrically connected to the first conductive pattern CP1 through a fifth contact hole CH5 penetrating through the sixth insulating layer GI6. In addition, the fifth conductive pattern CP5 may be electrically connected to the third drain region D3 of the third active layer ACT3 through a sixth contact hole CH6 penetrating through the sixth insulating layer GI6.

In an embodiment, the fifth conductive pattern CP5 may be a drain electrode of the third transistor T3 and may also be considered as a configuration included in the third transistor T3.

The sixth conductive pattern CP6 may be electrically connected to the third conductive pattern CP3 by penetrating through an insulating layer disposed between the fourth conductive layer GTL4 and the fifth conductive layer SDL1. Specifically, the sixth conductive pattern CP6 may be electrically connected to the third conductive pattern CP3 through a seventh contact hole CH7 penetrating through the sixth insulating layer GI6. In addition, the sixth conductive pattern CP6 may be electrically connected to the second source region S2 through an eighth contact hole CH8 penetrating through the sixth insulating layer GI6. In an embodiment, the sixth conductive pattern CP6 may be a source electrode of the second transistor T2 and may also be considered as a configuration included in the second transistor T2.

In an embodiment, the second capacitor electrode CPE2 may overlap the data line DL connected to the pixel PX. The second capacitor electrode CPE2 and the data line DL may form a second capacitor C2. The second capacitor electrode CPE2 and the data line DL may form a first electrode and a second electrode of the second capacitor C2, respectively.

The second capacitor electrode CPE2 may be electrically connected to the second drain region D2 of the second active layer ACT2 and the third source region S3 of the third active layer ACT3 by penetrating through a plurality of insulating layers disposed between the second semiconductor layer SCL2 and the fifth conductive layer SDL1.

In an embodiment, the second capacitor electrode CPE2 may be a drain electrode of the second transistor T2 and a source electrode of the third transistor T3, and may also be considered as a configuration included in the second transistor T2 and the third transistor T3.

In an embodiment, the ranges of the aspect ratio (“AR”), depth, and width of the fifth to ninth contact holes CH5, CH6, CH7, CH8, and CH9 are not limited to a predetermined range.

The first interlayer insulating layer ILD1 may be disposed on the sixth insulating layer GI6 and the fifth conductive layer SDL1. The first interlayer insulating layer ILD1 may cover an entirety of the fifth conductive layer SDL1.

The first interlayer insulating layer ILD1 may include an inorganic insulating material. In an embodiment, the first interlayer insulating layer ILD1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The sixth conductive layer SDL2 may be disposed on the first interlayer insulating layer ILD1. The sixth conductive layer SDL2 may include a conductive material. In embodiments, the conductive material are omitted.

The sixth conductive layer SDL2 may include the data line DL connected to the pixel PX. The data line DL may form the second capacitor C2 together with the second capacitor electrode CPE2. The redundant descriptions will be omitted.

The second interlayer insulating layer ILD2 may be disposed on the first interlayer insulating layer ILD1 and the sixth conductive layer SDL2. The second interlayer insulating layer ILD2 may cover an entirety of the sixth conductive layer SDL2.

The second interlayer insulating layer ILD2 may include the inorganic insulating material included in the first interlayer insulating layer ILD1. In embodiments, the inorganic insulating material are omitted.

The seventh conductive layer SDL3 may be disposed on the second interlayer insulating layer ILD2. The seventh conductive layer SDL3 may include a conductive material. In embodiments, the conductive material are omitted.

The seventh conductive layer SDL3 may include a seventh conductive pattern CP7, an eighth conductive pattern CP8, and a ninth conductive pattern CP9.

The seventh conductive pattern CP7 may be electrically connected to the fifth conductive pattern CP5 by penetrating through a plurality of insulating layers disposed between the fifth conductive layer SDL1 and the seventh conductive layer SDL3. Specifically, the seventh conductive pattern CP7 may be electrically connected to the fifth conductive pattern CP5 through a tenth contact hole CH10 penetrating through the first interlayer insulating layer ILD1 and the second interlayer insulating layer ILD2. The seventh conductive pattern CP7 may be connected to the first conductive pattern CP1 and the first drain region D1 of the first active layer ACT1 through the fifth conductive pattern CP5.

In an embodiment, the aspect ratio (“AR”), width, and depth of the tenth contact hole CH10 are not limited.

The eighth conductive pattern CP8 may be disposed on the second interlayer insulating layer ILD2. The eighth conductive pattern CP8 may include a conductive material. In embodiments, the conductive material are omitted.

The eighth conductive pattern CP8 may be a voltage line of the pixel PX.

The eighth conductive pattern CP8 may be electrically connected to the second conductive pattern CP2 by penetrating through a plurality of insulating layers disposed between the fourth conductive layer GTL4 and the seventh conductive layer SDL3. Specifically, the eighth conductive pattern CP8 may be electrically connected to the second conductive pattern CP2 through an eleventh contact hole CH11 defined in the sixth insulating layer GI6, the first interlayer insulating layer ILD1, and the second interlayer insulating layer ILD2, and may be electrically connected to the first source region S1 of the first active layer ACT1 through the second conductive pattern CP2.

The ninth conductive pattern CP9 may be disposed on the second interlayer insulating layer ILD2. The ninth conductive pattern CP9 may include a conductive material. In embodiments, the conductive material are omitted. In an embodiment, the ninth conductive pattern CP9 may be an initialization voltage line of the pixel PX.

The ninth conductive pattern CP9 may be electrically connected to the fourth conductive pattern CP4 by penetrating through a plurality of insulating layers disposed between the fourth conductive layer GTL4 and the seventh conductive layer SDL3. Specifically, the ninth conductive pattern CP9 may be electrically connected to the fourth conductive pattern CP4 through a twelfth contact hole CH12 defined in the sixth insulating layer GI6, the first interlayer insulating layer ILD1, and the second interlayer insulating layer ILD2, and may be electrically connected to the first capacitor electrode CPE1 through the fourth conductive pattern CP4.

In an embodiment, the eleventh contact hole CH11 and the twelfth contact hole CH12 may be defined by penetrating through at least three or more insulating layers, and accordingly, the eleventh contact hole CH11 and the twelfth contact hole CH12 may have the range of the aspect ratio (“AR”), width, and depth of the contact holes described above. The redundant descriptions will be omitted.

The via layer VIA may be disposed on the second interlayer insulating layer ILD2 and the seventh conductive layer SDL3. The via layer VIA may cover an entirety of the seventh conductive layer SDL3.

The via layer VIA may include an organic material. In an embodiment, the via layer VIA may include an acrylic resin, an epoxy resin, a phenolic resin, a polyamide resin, or a PI resin.

The display element layer EML may be disposed on the transistor layer TFTL. The display element layer EML may include a light emitting element ED and a pixel defining layer PDL. The light emitting element ED may include an anode electrode AE, a light emitting layer EL, and a cathode electrode CE.

The anode electrode AE of the light emitting element ED may be disposed on the via layer VIA. The anode electrode AE may be connected to the seventh conductive pattern CP7 of the seventh conductive layer SDL3 through an anode contact hole VH penetrating through the via layer VIA.

The anode electrode AE may be formed as a single layer including or consisting of silver (Ag), molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and indium tin oxide (“ITO”), an APC alloy, and a stacked structure (“ITO/APC/ITO”) of an APC alloy and ITO. The APC alloy may be an alloy of silver (Ag), palladium (Pd), and copper (Cu).

The pixel defining layer PDL may be disposed on the via layer VIA. The pixel defining layer PDL may define the light emitting area EA and may expose the anode electrode AE in a portion overlapping the light emitting area EA. The pixel defining layer PDL may cover an edge of the anode electrode AE.

The pixel defining layer PDL may include an organic material or an inorganic material.

In an embodiment, when the pixel defining layer PDL includes the organic material, the pixel defining layer PDL may include an acryl resin, an epoxy resin, a phenolic resin, a polyamide resin, a PI resin, or the like.

In an embodiment, when the pixel defining layer PDL includes the inorganic material, the pixel defining layer PDL may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The light emitting layer EL of the light emitting element ED may be disposed on the anode electrode AE. The light emitting layer EL may include an organic material to emit light of a predetermined color. In an embodiment, the light emitting layer EL may include a hole transporting layer, an organic material layer, and an electron transporting layer, for example. The organic material layer may include a host and a dopant. The organic material layer may include a material that emits a predetermined light and may include or consist of a phosphorescent material or a fluorescent material.

The cathode electrode CE of the light emitting element ED may be disposed on the light emitting layer EL. The cathode electrode CE may be disposed to cover the light emitting layer EL. The cathode electrode CE may be a common layer commonly disposed on the plurality of light emitting layers EL.

The cathode electrode CE may include or consist of a transparent conductive material (“TCO”) such as ITO or IZO capable of transmitting light, or a semi-transmissive conductive material such as magnesium (Mg), silver (Ag), or an alloy of magnesium (Mg) and silver (Ag). When the cathode electrode CE includes or consists of the semi-transmissive conductive material, light emitting efficiency may be increased by a micro cavity.

The encapsulation layer TFEL may be formed on the display element layer EML. The encapsulation layer TFEL may include at least one inorganic film to prevent oxygen or moisture from permeating into the display element layer EML, and may include at least one organic film to protect the display element layer EML from foreign substances such as dust.

The encapsulation layer TFEL may include a first encapsulation layer TFE1, a second encapsulation layer TFE2, and a third encapsulation layer TFE3.

The first encapsulation layer TFE1 may be disposed on the cathode electrode CE and may cover an entirety of the cathode electrode CE.

The first encapsulation layer TFE1 may include an inorganic insulating material, e.g., silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second encapsulation layer TFE2 may be disposed on the first encapsulation layer TFE1 and may cover an entirety of the first encapsulation layer TFE1. The second encapsulation layer TFE2 may planarize a level difference formed by the first encapsulation layer TFE1.

The second encapsulation layer TFE2 may include an organic material and may be an organic film including or consisting of an acrylic resin, an epoxy resin, a silicone resin, a silicone-acryl resin, a phenolic resin, a polyamide resin, or a PI resin.

The third encapsulation layer TFE3 may be disposed on the second encapsulation layer TFE2 and may cover an entirety of the second encapsulation layer TFE2.

The third encapsulation layer TFE3 may include an inorganic insulating material, e.g., silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

In an embodiment, the display device 10 may further include an optical layer disposed on the encapsulation layer TFEL. The optical layer may include at least one of a color filter layer (e.g., a color filter layer including color filters corresponding to a light emitting color of each pixel PX) and a light conversion layer (e.g., a light conversion layer including wavelength conversion patterns that convert a color or wavelength of light emitted from the light emitting elements ED of at least some pixels PX).

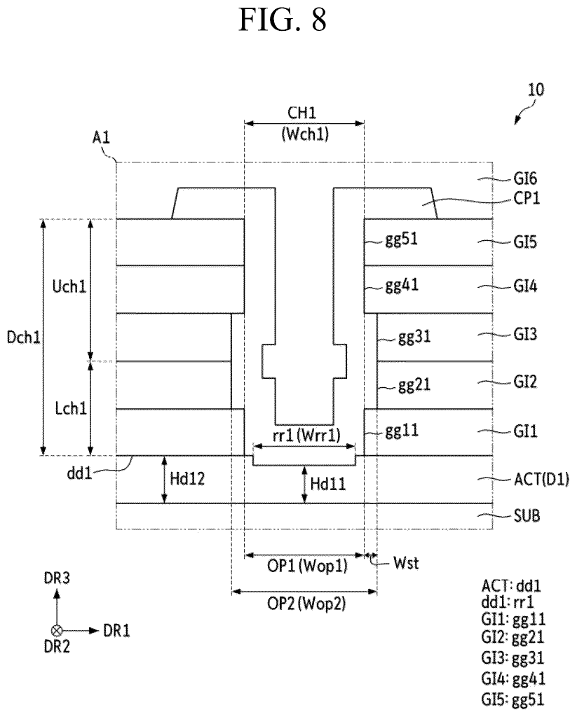

FIG. 8 is an enlarged cross-sectional view of area ‘A1’ of FIG. 7.

Referring to FIG. 8 in addition to FIGS. 1 to 7, the first contact hole CH1 may be defined to collectively penetrate through the first to fifth insulating layers GI1, GI2, GI3, GI4, and GI5. As described above, the display device 10 in an embodiment may include the contact holes having a narrow and deep shape. Accordingly, the step coverage characteristic of the conductive pattern covering the inside of the contact hole in an embodiment may be relatively lower in a lower area than that in an upper area of the contact hole. A detailed description thereof will be provided later.

An aspect ratio (“AR”) of the first contact hole CH1 may be defined as a value obtained by dividing a depth Dch1 of the first contact hole CH1 by a width Wch1 of the first contact hole CH1 (e.g., depth Dch1/width Wch1).

In an embodiment, the aspect ratio (“AR”) of the first contact hole CH1 may be 0.6 or greater. In addition, the width Wch1 of the first contact hole CH1 may be 2.0 micrometers or less, and the depth Dch1 thereof may be 1.2 micrometers or more.

In an embodiment, the first contact hole CH1 may include a lower area Lch1 and an upper area Uch1. The lower area Lch1 of the first contact hole CH1 may be an area relatively close to the substrate SUB, and the upper area Uch1 of the first contact hole CH1 may be an area relatively far from the substrate SUB.

In an embodiment, the first insulating layer GI1 and the second insulating layer GI2 may be disposed in a portion overlapping the lower area Lch1 of the first contact hole CH1, and the third insulating layer GI3, the fourth insulating layer GI4, and the fifth insulating layer GI5 may be disposed in a portion overlapping the upper area Uch1 of the first contact hole CH1.

The first active layer ACT1 may be disposed in contact with the substrate SUB. For convenience of explanation, a portion overlapping the first drain region D1 of the first active layer ACT1 is enlarged and then described, but the structure to which the embodiment is applied is not limited thereto. In an embodiment, the first source region S1 of the first active layer ACT1 disposed in the portion overlapping the second contact hole CH2 may have the same structure and characteristics as the first drain region D1 of the first active layer ACT1 overlapping the first contact hole CH1.

The first active layer ACT1 may include a semiconductor material (e.g., polysilicon). As the first active layer ACT1 includes a polysilicon semiconductor material, it may have relatively high mobility.

In an embodiment, the first active layer ACT1 may include a first surface dd1. The first surface dd1 may be one surface facing the first insulating layer GI1.

The first surface dd1 of the first active layer ACT1 may define a recessed area rr1 in a portion overlapping the first contact hole CH1. The recessed area rr1 may refer to an area where a portion of the first surface dd1 overlapping the first contact hole CH1 is depressed toward a portion facing the substrate SUB. The recessed area rr1 of the first active layer ACT1 may be defined by performing a dry etching process during the process of fabricating the display device 10. The fabricating process thereof will be described later.

The first active layer ACT1 may have a first height Hd11 of a portion overlapping the recessed area rr1 and a second height Hd12 of a portion that does not overlap the recessed area rr1. The first height Hd11 and the second height Hd12 may be different from each other. In an embodiment, the first height Hd11 may be lower than the second height Hd12.

A width Wrr1 of the recessed area rr1 in the first direction DR1 may be smaller than the width Wch1 of the first contact hole CH1. Accordingly, the first active layer ACT1 may have a step-shaped level difference in the portion overlapping the first contact hole CH1.

The first insulating layer GI1 may be disposed on the first active layer ACT1. The first insulating layer GI1 may be disposed in contact with the first active layer ACT1. The first insulating layer GI1 may not overlap the recessed area rr1 of the first active layer ACT1 in the third direction DR3.

The first insulating layer GI1 may define a first opening OP1 in the portion overlapping the first contact hole CH1, and may be disposed to surround the first opening OP1. The first insulating layer GI1 may expose the first active layer ACT1 in a portion overlapping the first opening OP1. Specifically, the first insulating layer GI1 may expose the recessed area rr1 of the first active layer ACT1 in the portion overlapping the first opening OP1.

The first insulating layer GI1 may include an inorganic insulating material. In an embodiment, the first insulating layer GI1 may include silicon oxide (e.g., SiO₂ or SiOx).

The first insulating layer GI1 may improve the properties of the polysilicon included in the first semiconductor layer SCL1 and at the same time perform an insulating function between the first semiconductor layer SCL1 and the first conductive layer GTL1.

The second insulating layer GI2 may be disposed on the first insulating layer GI1. The second insulating layer GI2 may be disposed in contact with the first insulating layer GI1. The second insulating layer GI2 may not overlap the recessed area rr1 of the first active layer ACT1 in the third direction DR3.

The second insulating layer GI2 may define a second opening OP2 in the portion overlapping the first contact hole CH1, and may be disposed to surround the second opening OP2.

In an embodiment, a width Wop2 of the second opening OP2 defined by the second insulating layer GI2 may be greater than a width Wop1 of the first opening OP1 defined by the first insulating layer GI1. A difference Wst between the width Wop2 of the second opening OP2 and the width Wop1 of the first opening OP1 may have a value of 10 angstroms or more and 300 angstroms or less.

The second insulating layer GI2 may include an inorganic insulating material. However, the second insulating layer GI2 may include an inorganic insulating material different from that of the first insulating layer GI1. In an embodiment, the second insulating layer GI2 may include silicon nitride (e.g., Si₃N₄ or SiNx).

The second insulating layer GI2 may have higher moisture permeation prevention characteristics than that of the first insulating layer GI1 and at the same time perform an insulating function between the first conductive layer GTL1 and the second conductive layer GTL2.

In an embodiment, a side surface gg11 of the first insulating layer GI1 may protrude further in a direction toward the first contact hole CH1 than a side surface gg21 of the second insulating layer GI2. Accordingly, the first insulating layer GI1 and the second insulating layer GI2 may form a step-shaped level difference.

In other words, the display device 10 in an embodiment may include a step-shaped level difference in which the recessed area rr1 of the first active layer ACT1, the first insulating layer GI1, and the second insulating layer GI2 are sequentially defined or formed in a portion overlapping the lower region Lch1 of the first contact hole CH1.

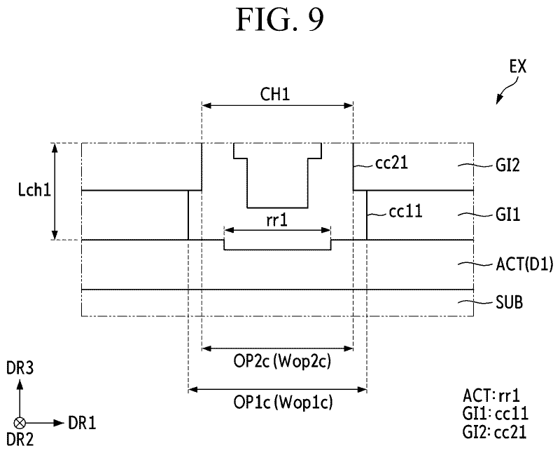

FIG. 9 is an enlarged cross-sectional view of a lower area of a first contact hole of FIG. 8 according to a comparative example.

Referring to FIGS. 8 and 9, a first contact hole CH1 defined in a display device EX according to the comparative example may have an aspect ratio (“AR”), width, and depth within the same range as the first contact hole CH1 defined in the display device 10.

In addition, a first active layer ACT1 included in the display device EX according to the comparative example may have the same structure and characteristics as the first active layer ACT1 included in the display device 10. In an embodiment, the first active layer ACT1 may include a recessed area rr1 in a portion overlapping the first contact hole CH1, and as the first active layer ACT1 defines the recessed area rr1, it may have a step-shaped level difference in the portion overlapping the first contact hole CH1.

In addition, each of a first insulating layer GI1 and a second insulating layer GI2 included in the display device EX according to the comparative example may include the same material as each of the first insulating layer GI1 and the second insulating layer GI2 included in the display device 10.

Hereinafter, a description of the common structure of the display device EX according to the comparative example and the display device 10 will be omitted and the differences therebetween will be described.

The first insulating layer GI1 included in the display device EX according to the comparative example may define a first opening OP1c in the portion overlapping the first contact hole CH1, and may be disposed to surround the first opening OP1c. The first insulating layer GI1 may expose the recessed area rr1 of the first active layer ACT1 in a portion overlapping the first opening OP1c.

The second insulating layer GI2 may be disposed on the first insulating layer GI1. The second insulating layer GI2 may be disposed in contact with the first insulating layer GI1.

The second insulating layer GI2 included in the display device EX according to the comparative example may define a second opening OP2c in the portion overlapping the first contact hole CH1, and may be disposed to surround the second opening OP2c. A width Wop2c of the second opening OP2c included in the display device EX according to the comparative example may be smaller than a width Wop1c of the first opening OP1c.

A side surface cc21 of the second insulating layer GI2 included in the display device EX according to the comparative example may protrude further in a direction toward the first contact hole CH1 than a side surface cc11 of the first insulating layer GI1. Accordingly, an undercut may be formed between the side surface cc11 of the first insulating layer GI1 and the second insulating layer GI2. In other words, the first insulating layer GI1 and the second insulating layer GI2 included in the display device EX according to the comparative example may form an overhang structure.

The first insulating layer GI1 and the second insulating layer GI2 included in the display device EX according to the comparative example may have an undercut shape by performing a cleaning process using a wet buffered oxide etchant (“BOE”) in a process of fabricating the display device EX.

In an embodiment, when an undercut is formed between the first insulating layer GI1 and the second insulating layer GI2 in a portion overlapping a lower area Lch1 of the first contact hole CH1, step coverage characteristics of the first conductive pattern CP1 may be significantly degraded in a portion overlapping the undercut, for example.

The degradation in the step coverage characteristic of the first conductive pattern CP1 may cause a contact defect of the first conductive pattern CP1. In an embodiment, the contact defect may include both a defect in which a thickness of the first conductive pattern CP1 is formed thinner than an appropriate range and a defect in which the first conductive pattern CP1 is disconnected.

Therefore, the display device 10 in an embodiment may propose a structure in which no undercut occurs between the first insulating layer GI1 and the second insulating layer GI2 in the portion overlapping the lower area Lch1 of the first contact hole CH1.

Referring back to FIG. 8, the display device 10 in an embodiment may structurally increase the step coverage characteristics of the first conductive pattern CP1 in the portion overlapping the lower area Lch1 by forming the first insulating layer GI1 to protrude further toward the first contact hole CH1 than the second insulating layer GI2 in the portion overlapping the lower area Lch1 of the first contact hole CH1. Therefore, the first conductive pattern CP1 in an embodiment may cover an entirety of the recessed area rr1 of the first active layer ACT1, the first insulating layer GI1, and the second insulating layer GI2 in the portion overlapping the lower area Lch1 without contact defects.

The third insulating layer GI3, the fourth insulating layer GI4, and the fifth insulating layer GI5 in an embodiment may be disposed in a portion overlapping the upper area Uch1 of the first contact hole CH1.

The third insulating layer GI3 may be disposed on the second insulating layer GI2. The third insulating layer GI3 may be disposed in contact with the second insulating layer GI2. The third insulating layer GI3 may not overlap the recessed area rr1 of the first active layer ACT1 in the third direction DR3.

The third insulating layer GI3 may include an inorganic insulating material. In an embodiment, the third insulating layer GI3 may include silicon nitride (e.g., Si₃N₄ or SiNx).

The third insulating layer GI3 may have relatively high moisture permeation prevention characteristics and at the same time perform an insulating function between the second conductive layer GTL2 and the third conductive layer GTL3.

The third insulating layer GI3 may define a second opening OP2 in the portion overlapping the first contact hole CH1, and may be disposed to surround the second opening OP2.

In an embodiment, a side surface gg31 of the third insulating layer GI3 may be disposed on the same line as the side surface gg21 of the second insulating layer GI2.

As the second insulating layer GI2 and the third insulating layer GI3 include the same material, the second insulating layer GI2 and the third insulating layer GI3 may have the same etch rate regardless of process conditions when performing a dry cleaning process in the process of fabricating the display device 10. Accordingly, the side surface gg31 of the third insulating layer GI3 may be disposed on the same line as the side surface gg21 of the second insulating layer GI2. The above-described same line means that there may be a process deviation of less than 10%.

The fourth insulating layer GI4 may be disposed on the third insulating layer GI3. The fourth insulating layer GI4 may be disposed in contact with the third insulating layer GI3. The fourth insulating layer GI4 may not overlap the recessed area rr1 of the first active layer ACT1 in the third direction DR3.

The fourth insulating layer GI4 may include an inorganic insulating material. In an embodiment, the fourth insulating layer GI4 may include at least one of silicon oxide (e.g., SiO₂ or SiOx) and silicon nitride (e.g., Si₃N₄ or SiNx).

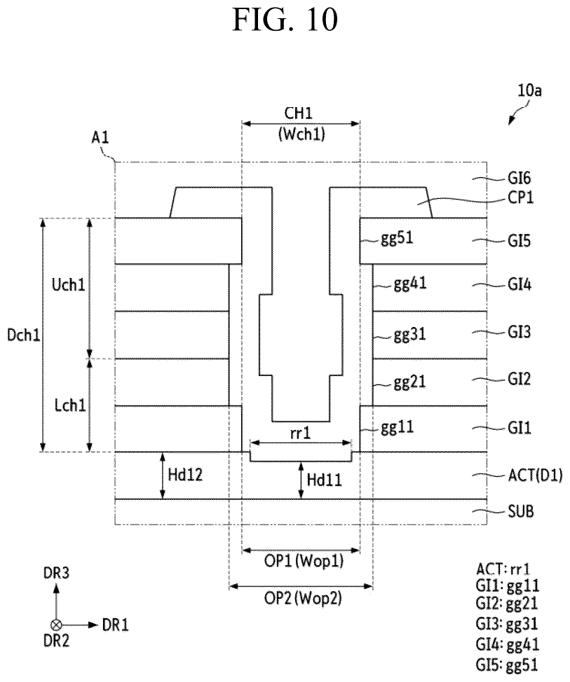

FIG. 10 is an enlarged cross-sectional view of area ‘A1’ of FIG. 7.

Referring to FIGS. 8 and 10, the fourth insulating layer GI4 may have various structural characteristics depending on the material it includes.

In an embodiment, when the fourth insulating layer GI4 includes silicon oxide (e.g., SiO₂ or SiOx), the fourth insulating layer GI4 may define the first opening OP1 in the portion overlapping the first contact hole CH1, as illustrated in FIG. 8, and may be disposed to surround the first opening OP1, for example.

In this case, a side surface gg41 of the fourth insulating layer GI4 may protrude further in a direction toward the first contact hole CH1 than the side surface gg31 of the third insulating layer GI3, and an undercut may be formed between the side surface gg31 of the third insulating layer GI3 and the fourth insulating layer GI4.

In some embodiments, as the third insulating layer GI3 and the fourth insulating layer GI4 include different materials from each other, the third insulating layer GI3 and the fourth insulating layer GI4 may have different etch rates depending on process conditions when performing a dry cleaning process in the process of fabricating the display device 10. Accordingly, the undercut may be formed between the side surface gg31 of the third insulating layer GI3 and the fourth insulating layer GI4.

In an embodiment, when the fourth insulating layer GI4 includes silicon nitride (e.g., Si₃N₄ or SiNx), the fourth insulating layer GI4 included in the display device 10a may define the second opening OP2 in the portion overlapping the first contact hole CH1, as illustrated in FIG. 10, and may be disposed to surround the second opening OP2, for example.

In this case, the side surface gg41 of the fourth insulating layer GI4 included in the display device 10a may be disposed on the same line as the side surface gg31 of the third insulating layer GI3.

In some embodiments, as the third insulating layer GI3 and the fourth insulating layer GI4 include the same material, the third insulating layer GI3 and the fourth insulating layer GI4 may have the same etch rate regardless of process conditions when performing a dry cleaning process in the process of fabricating the display device 10. Accordingly, the side surface gg31 of the third insulating layer GI3 may be disposed on the same line as the side surface gg41 of the fourth insulating layer GI4. The above-described same line means that there may be a process deviation of less than 10%.

In an embodiment, the fifth insulating layer GI5 may be disposed on the fourth insulating layer GI4. The fifth insulating layer GI5 may be disposed in contact with the fourth insulating layer GI4. The fifth insulating layer GI5 may not overlap the recessed area rr1 of the first active layer ACT1 in the third direction DR3.

The fifth insulating layer GI5 may include an inorganic insulating material. In an embodiment, the fifth insulating layer GI5 may include silicon oxide (e.g., SiO₂ or SiOx).

The fifth insulating layer GI5 may define a first opening OP1 in the portion overlapping the first contact hole CH1, and may be disposed to surround the first opening OP1.

In some embodiments, when the fourth insulating layer GI4 includes silicon oxide (e.g., SiO₂ or SiOx), a side surface gg51 of the fifth insulating layer GI5 may be disposed on the same line as the side surface gg41 of the fourth insulating layer GI4, as illustrated in FIG. 8. The above-described same line means that there may be a process deviation of less than 10%. The redundant descriptions will be omitted.

In some embodiments, when the fourth insulating layer GI4 includes silicon nitride (e.g., Si₃N₄ or SiNx), the side surface gg51 of the fifth insulating layer GI5 included in the display device 10a may protrude further in a direction toward the first contact hole CH1 than the side surface gg41 of the fourth insulating layer GI4, as illustrated in FIG. 10. Accordingly, an undercut may be formed between the fifth insulating layer GI5 and the fourth insulating layer GI4 included in the display device 10a in the direction toward the first contact hole CH1. The redundant descriptions will be omitted.

As described above, the first conductive pattern CP1 may have relatively high step coverage characteristics in the portion that overlaps the upper area Uch1 rather than the lower area Lch1 of the first contact hole CH1. Therefore, the first conductive pattern CP1 may cover the third insulating layer GI3, the fourth insulating layer GI4, and the fifth insulating layer GI5 without contact defects even when the undercut is formed between the third insulating layer GI3, the fourth insulating layer GI4, and the fifth insulating layer GI5 in the portion overlapping the upper area Uch1.

The first conductive pattern CP1 may be formed to have a uniform thickness along a profile of the lower structure. Accordingly, the first conductive pattern CP1 may include a step in the portion overlapping the first contact hole CH1. The step formed by the first conductive pattern CP1 in the portion overlapping the first contact hole CH1 may be planarized by the sixth insulating layer GI6.

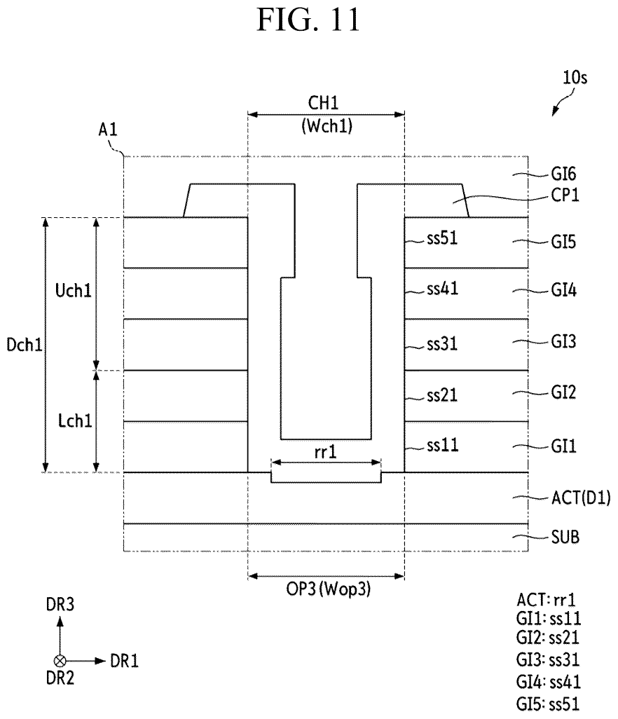

FIG. 11 is an enlarged cross-sectional view of another embodiment of area ‘A1’ of FIG. 7.

Referring to FIG. 11 in addition to FIGS. 1 to 10, a first contact hole CH1 defined in a display device 10s may have an aspect ratio (“AR”), width, and depth within the same range as the first contact hole CH1 defined in the display device 10.

In addition, a first active layer ACT1 included in the display device 10s may have the same structure and characteristics as the first active layer ACT1 included in the display device 10. In an embodiment, the first active layer ACT1 may define a recessed area rr1 in a portion overlapping the first contact hole CH1, and as the first active layer ACT1 defines the recessed area rr1, it may have a step-shaped level difference in the portion overlapping the first contact hole CH1.

In addition, a first insulating layer GI1 and a second insulating layer GI2 included in the display device 10s may be disposed in a portion overlapping the lower area Lch1 of the first contact hole CH1, and a third insulating layer GI3, a fourth insulating layer GI4, and a fifth insulating layer GI5 may be disposed in a portion overlapping the upper area Uch1 of the first contact hole CH1.

Hereinafter, a description of the common structure of the display device 10s and the display device 10 will be omitted and the differences therebetween will be described.

The first insulating layer GI1 included in the display device 10s may define a third opening OP3 in the portion overlapping the first contact hole CH1, and may be disposed to surround the third opening OP3. The first insulating layer GI1 may expose the first active layer ACT1 in a portion overlapping the third opening OP3. Specifically, the first insulating layer GI1 may expose the recessed area rr1 of the first active layer ACT1 in the portion overlapping the third opening OP3.

A width Wop3 of the third opening OP3 included in the display device 10s may be the same as the width Wch1 of the first contact hole CH1.

The first insulating layer GI1 included in the display device 10s may include the same material as that of the first insulating layer GI1 included in the display device 10.

The second insulating layer GI2 included in the display device 10s may be disposed on the first insulating layer GI1. The second insulating layer GI2 may be disposed in contact with the first insulating layer GI1.

The second insulating layer GI2 may define a third opening OP3 in the portion overlapping the first contact hole CH1, and may be disposed to surround the third opening OP3.

The second insulating layer GI2 included in the display device 10s may include the same material as that of the second insulating layer GI2 included in the display device 10.

A side surface ss11 of the first insulating layer GI1 included in the display device 10s may be disposed on the same line as the side surface ss21 of the second insulating layer GI2. The above-described same line means that there may be a process deviation of less than 10%.

The third insulating layer GI3 included in the display device 10s may be disposed on the second insulating layer GI2. The third insulating layer GI3 may be disposed in contact with the second insulating layer GI2.

The third insulating layer GI3 may define a third opening OP3 in the portion overlapping the first contact hole CH1, and may be disposed to surround the third opening OP3.

The third insulating layer GI3 included in the display device 10s may include the same material as that of the third insulating layer GI3 included in the display device 10.

The side surface ss21 of the second insulating layer GI2 included in the display device 10s may be disposed on the same line as a side surface ss31 of the third insulating layer GI3. The above-described same line means that there may be a process deviation of less than 10%.

A fourth insulating layer GI4 included in the display device 10s may be disposed on the third insulating layer GI3. The fourth insulating layer GI4 may be disposed in contact with the third insulating layer GI3.

The fourth insulating layer GI4 may define a third opening OP3 in the portion overlapping the first contact hole CH1, and may be disposed to surround the third opening OP3.

The fourth insulating layer GI4 included in the display device 10s may include the same material as that of the fourth insulating layer GI4 included in the display device 10.

The side surface ss31 of the third insulating layer GI3 included in the display device 10s may be disposed on the same line as a side surface ss41 of the fourth insulating layer GI4. The above-described same line means that there may be a process deviation of less than 10%.

A fifth insulating layer GI5 included in the display device 10s may be disposed on the fourth insulating layer GI4. The fifth insulating layer GI5 may be disposed in contact with the fourth insulating layer GI4.

The fifth insulating layer GI5 may define a third opening OP3 in the portion overlapping the first contact hole CH1, and may be disposed to surround the third opening OP3.

The fifth insulating layer GI5 included in the display device 10s may include the same material as that of the fifth insulating layer GI5 included in the display device 10.

The side surface ss41 of the fourth insulating layer GI4 included in the display device 10s may be disposed on the same line as a side surface ss51 of the fifth insulating layer GI5. The above-described same line means that there may be a process deviation of less than 10%.

The display device 10s in an embodiment may solve contact defects of the first conductive pattern CP1 by proposing a structure in which no undercut occurs between the first insulating layer GI1 and the second insulating layer GI2 in the portion overlapping the lower area Lch1 of the first contact hole CH1.

Specifically, the display device 10s in an embodiment may structurally increase the step coverage characteristics of the first conductive pattern CP1, as the side surface of the first insulating layer GI1 and the side surface of the second insulating layer GI2 are disposed on the same line in the portion overlapping the lower area Lch1 of the first contact hole CH1.

Therefore, the first conductive pattern CP1 in the portion overlapping the lower area Lch1 may cover an entirety of the recessed area rr1 of the first active layer ACT1, the first insulating layer GI1, and the second insulating layer GI2 without contact defects.

The dry cleaning process of the first to fifth insulating layers GI1, GI2, GI3, GI4, and GI5 included in the display device 10s may be performed at a predetermined temperature in the process of fabricating the display device 10s. Accordingly, the first to fifth insulating layers GI1, GI2, GI3, GI4, and GI5 included in the display device 10s may have the same etch rate in the dry cleaning process even when the first to fifth insulating layers GI1, GI2, GI3, GI4, and GI5 include different materials or the same materials. The fabricating process thereof will be described later.

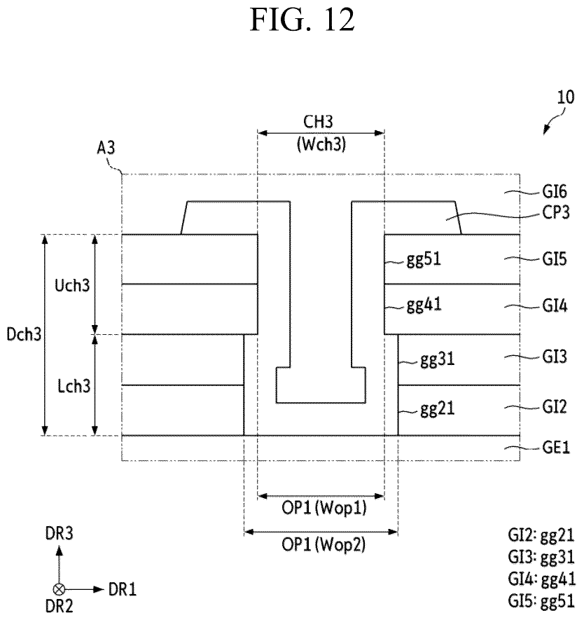

FIG. 12 is an enlarged cross-sectional view of area ‘A3’ of FIG. 7.

Referring to FIG. 12 in addition to FIGS. 1 to 11, in an embodiment, the third contact hole CH3 may be defined to collectively penetrate through the second to fifth insulating layers GI2, GI3, GI4, and GI5.

In an embodiment, an aspect ratio (“AR”) of the third contact hole CH3 may be 0.6 or greater. A width Wch3 of the third contact hole CH3 may be 2.0 micrometers or less, and a depth Dch3 thereof may be 1.2 micrometers or more.

The third contact hole CH3 may include a lower area Lch3 and an upper area Uch3. The lower area Lch3 of the third contact hole CH3 may be an area relatively close to the first gate electrode GE1, and the upper area Uch3 of the third contact hole CH3 may be an area relatively far from the first gate electrode GE1.

In an embodiment, the second insulating layer GI2 and the third insulating layer GI3 may be disposed in a portion overlapping the lower area Lch3 of the third contact hole CH3, and the fourth insulating layer GI4 and the fifth insulating layer GI5 may be disposed in a portion overlapping the upper area Uch3 of the third contact hole CH3.

The structure and characteristics of the second to fifth insulating layers GI2, GI3, GI4, and GI5 in a portion overlapping the third contact hole CH3 and a peripheral area of the third contact hole CH3 may be the same as the structure and characteristics of the second to fifth insulating layers GI2, GI3, GI4, and GI5 in a portion overlapping the first contact hole CH1 and a peripheral area of the first contact hole CH1.

Specifically, the second insulating layer GI2 and the third insulating layer GI3 may include silicon nitride (e.g., Si₃N₄ or SiNx). The second insulating layer GI2 and the third insulating layer GI3 may define a second opening OP2 in the portion overlapping the third contact hole CH3, and may be disposed to surround the second opening OP2. The side surface gg21 of the second insulating layer GI2 and the side surface gg31 of the third insulating layer GI3 may be disposed on the same line and may have a process deviation of less than 10%.

The redundant descriptions of the fourth insulating layer GI4 and the fifth insulating layer GI5 are omitted.

The display device 10 in an embodiment may solve contact defects of the third conductive pattern CP3 by proposing a structure in which no undercut occurs between the first insulating layer GI1 and the second insulating layer GI2 in the portion overlapping the lower area Lch3 of the third contact hole CH3.

Specifically, the display device 10 in an embodiment may structurally increase the step coverage characteristics of the third conductive pattern CP3, as the side surface of the first insulating layer GI1 and the side surface of the second insulating layer GI2 are disposed on the same line in the portion overlapping the lower area Lch3 of the third contact hole CH3.

Therefore, the third conductive pattern CP3 in the portion overlapping the lower area Lch3 may cover an entirety of the first gate electrode GE1, the second insulating layer GI2, and the third insulating layer GI3 without contact defects.

The third conductive pattern CP3 may be formed to have a uniform thickness along a profile of the lower structure. Accordingly, the third conductive pattern CP3 may include a step in the portion overlapping the third contact hole CH3. The step formed by the third conductive pattern CP3 in the portion overlapping the third contact hole CH3 may be planarized by the sixth insulating layer GI6.

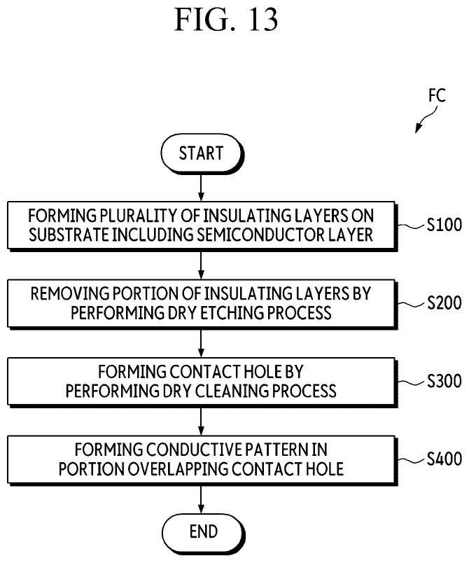

FIG. 13 is a flowchart illustrating a process of fabricating a first conductive pattern and a second conductive pattern overlapping the first contact hole and the second contact hole in FIG. 7.

Referring to FIG. 13, a method FC for fabricating a display device 10 in an embodiment may include an operation (S100) of forming a plurality of insulating layers on a substrate including a semiconductor layer, an operation (S200) of removing a portion of the insulating layers by performing a dry etching process, an operation (S300) of defining a contact hole by performing a dry cleaning process, and an operation (S400) of forming a conductive pattern in a portion overlapping the contact hole.

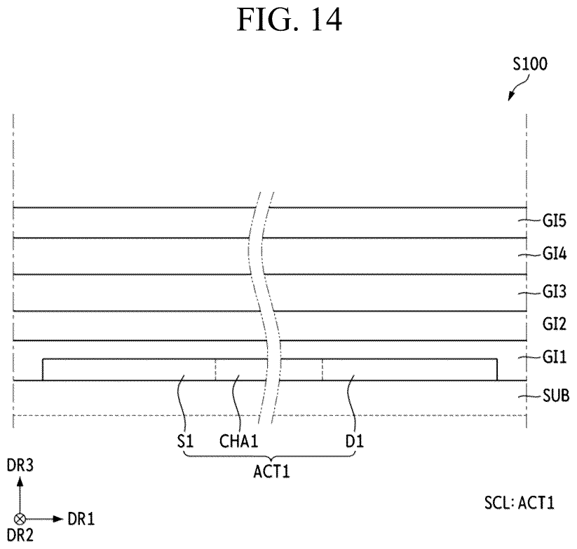

FIG. 14 is a cross-sectional view illustrating operation S100 of FIG. 13.

The operation (S100) of forming a plurality of insulating layers on a substrate including a semiconductor layer will be described with reference to FIG. 14 in addition to FIGS. 1 to 13.

First, a first active layer ACT1 included in a first semiconductor layer SCL1 is formed on a substrate SUB. The first active layer ACT1 may be divided into a plurality of regions with different properties. In an embodiment, the first active layer ACT1 may include a first channel region CHA1, a first source region S1, and a first drain region D1. The first source region S1 and the first drain region D1 may be more conductive regions than the first channel region CHA1. In the specification, the first active layer ACT1 may be also referred to as a semiconductor and/or a semiconductor layer.

In the process, the first active layer ACT1 may be formed through a semiconductor film deposition process and a semiconductor patterning process. For convenience of explanation, in FIG. 14, a portion overlapping the first channel region CHA1 is omitted, and a portion overlapping the first source region S1 and the first drain region D1 is enlarged and illustrated.

Next, first to fifth insulating layers GI1, GI2, GI3, GI4, and GI5 are sequentially formed on the first active layer ACT1. Each of the first to fifth insulating layers GI1, GI2, GI3, GI4, and GI5 may be formed through a deposition process of depositing the insulating material (e.g., the inorganic insulating material) as exemplified above.

A first conductive layer GTL1, a second conductive layer GTL2, and a third conductive layer GTL3 may be sequentially formed between the first to fifth insulating layers GI1, GI2, GI3, GI4, and GI5. Each of the first conductive layer GTL1, the second conductive layer GTL2, and the third conductive layer GTL3 may be formed by a metal film deposition process (e.g., a deposition process) and a metal patterning process (e.g., an etching process using a mask). The characteristics of the first conductive layer GTL1, the second conductive layer GTL2, and the third conductive layer GTL3 are the same as those described with reference to FIG. 7. The redundant descriptions will be omitted.

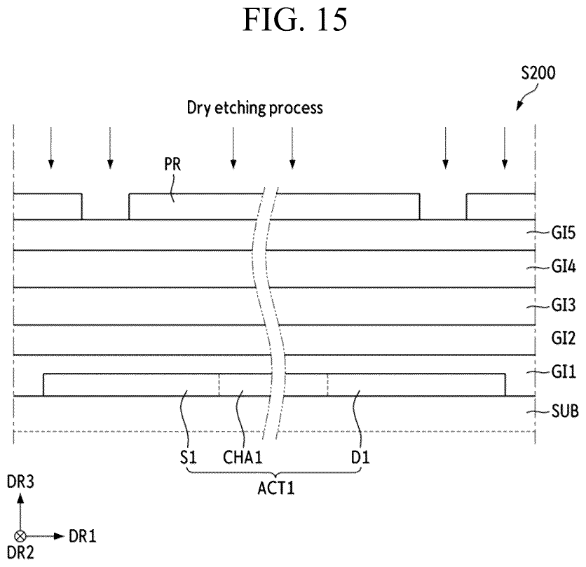

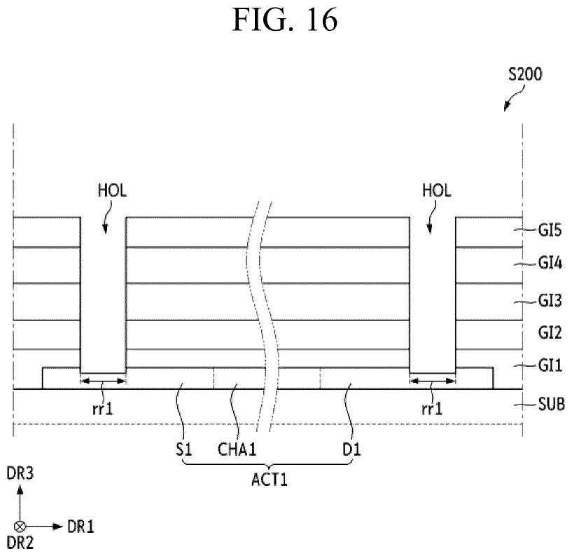

FIGS. 15 and 16 are cross-sectional views illustrating operation S200 of FIG. 13.

The operation (S200) of removing a portion of the insulating layers by performing a dry etching process will be described with reference to FIGS. 15 and 16.

First, a plurality of photoresists PR are formed on the fifth insulating layer GI5. In the process, the photoresists PR may be formed to expose a portion of the first source region S1 and a portion of the first drain region D1 of the first active layer ACT1.

Next, a dry etching process is performed. In an embodiment, the dry etching process may be performed through a reactive ion etching (“RIE”) process using reactive gases such as CHF₃, CH₃F, CH₂F₂, CHF₆, CF₄, C₂F₆, and C₃F₆, and sputtering gases such as Ar, and O₂/Ar. In this case, an inductively coupled plasma (“ICP”) source or a capacitively coupled plasma (“CCP”) source may be used as a plasma source, for example.

In the process, portions of the first to fifth insulating layers GI1, GI2, GI3, GI4, and GI5 that do not overlap the photoresist PR may be removed at once, and as a result, a hole HOL may be defined in a portion overlapping the first source region S1 and the first drain region D1 of the first active layer ACT1. The first active layer ACT1 may be exposed in a portion overlapping the hole HOL.

In the process, the first active layer ACT1 may define a recessed area rr1 in the portion overlapping the first source region S1 and the first drain region D1. The recessed area rr1 of the first active layer ACT1 may be formed by removing a portion of the first active layer ACT1 through the dry etching process.

In the process, the first to fifth insulating layers GI1, GI2, GI3, GI4, and GI5 may be isotropically removed. Accordingly, the first to fifth insulating layers GI1, GI2, GI3, GI4, and GI5 may have uniform side surfaces in the portion overlapping the hole HOL.

As described above, the first active layer ACT1 may include polysilicon. As a result, etching residues such as native oxide may be formed inside the hole HOL after the dry etching process. Therefore, for the display device 10 in an embodiment, a cleaning process of removing the etching residues may be necessarily performed after the dry etching process.

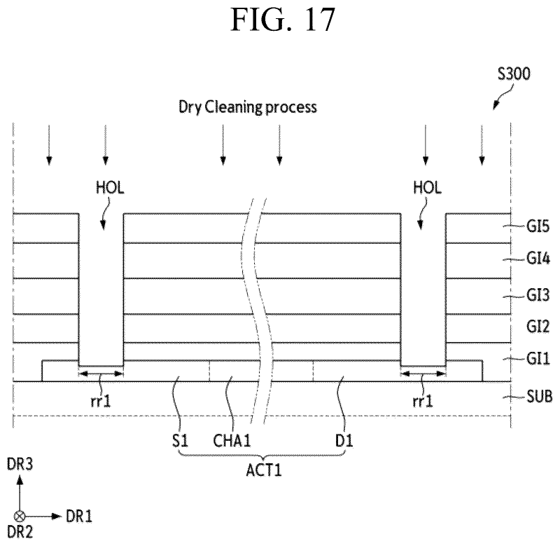

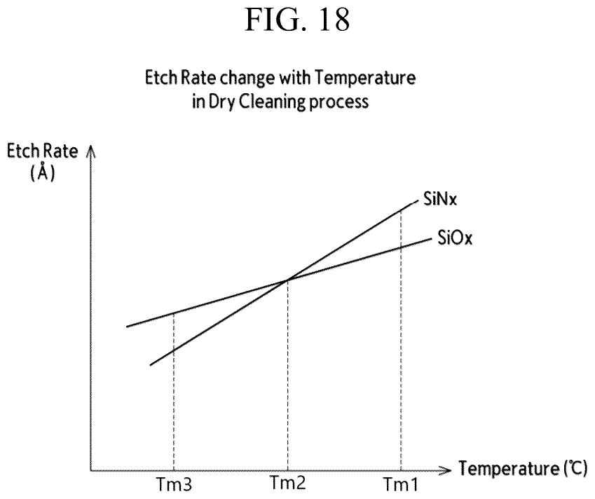

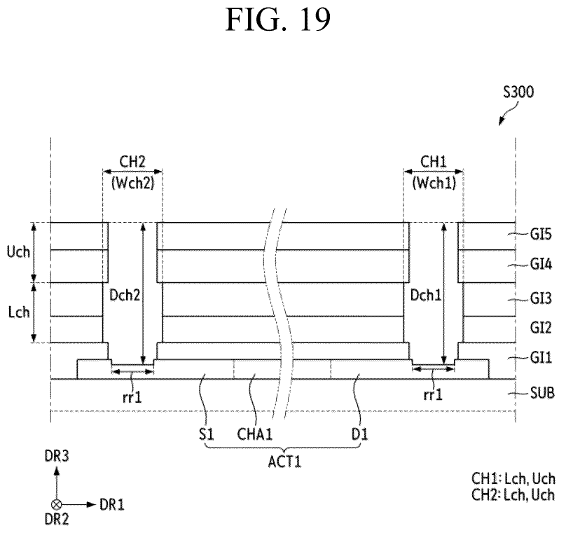

FIGS. 17 and 19 are cross-sectional views illustrating operation S300 of FIG. 13 and FIG. 18 is a graph illustrating an etch rate change of an inorganic material according to temperature change in a dry cleaning process.

The operation (S300) of defining a contact hole by performing a dry cleaning process will be described with reference to FIGS. 17 to 19.

Next, a dry cleaning process is performed. In an embodiment, the dry cleaning process may be performed using hydrofluoric acid (HF) gas, for example. The process may be performed without a separate mask or photoresist.

In the process, all etching residues included in the display device 10 may be removed, and in addition, portions of the first to fifth insulating layers GI1, GI2, GI3, GI4, and GI5 overlapping the hole HOL may be removed.

In the process, the dry cleaning process may be performed while changing process conditions such as temperature, pressure, and HF gas flow rate. Among the process conditions of the dry cleaning process described above, the temperature may be a main factor affecting the etch rate of the inorganic material.

As described above, the first insulating layer GI1 and the fifth insulating layer GI5 in an embodiment may include silicon oxide (e.g., SiO₂ or SiOx), the second insulating layer GI2 and the third insulating layer GI3 may include silicon nitride (e.g., Si₃N₄ or SiNx), and the fourth insulating layer GI4 may include at least one of silicon nitride (e.g., Si₃N₄ or SiNx) and silicon oxide (e.g., SiO₂ or SiOx).

In the process, the shapes of the first to fifth insulating layers GI1, GI2, GI3, GI4, and GI5 overlapping the hole HOL may be variously formed depending on the temperature of the dry cleaning process.

Referring to FIG. 18 in addition to FIGS. 1 to 17, the illustrated graph illustrates the etch rate change of inorganic material according to temperature change in the dry cleaning process. In the graph, an X-axis may represent a process temperature (in terms of degrees Celsius (° C.)), and a Y-axis may represent an etch rate (in terms of angstrom (A)) of the inorganic material.

In the illustrated graph, a first temperature Tm1 may represent the highest temperature, and a third temperature Tm3 may represent the lowest temperature. In an embodiment, the process temperature may be adjusted within a range of 0° C. to 100° C. The first temperature Tm1 and the third temperature Tm3 may have an absolute value deviation of 5° C. or more and 10° C. or less based on a second temperature Tm2.

As illustrated in the graph, when the dry cleaning process is performed at the second temperature Tm2, the etch rate of silicon nitride (e.g., Si₃N₄ or SiNx) and the etch rate of silicon oxide (e.g., SiO₂ or SiOx) may be the same.

This may mean that when the process is performed at the second temperature Tm2, the first insulating layer GI1 including silicon oxide (e.g., SiO₂ or SiOx) and the second insulating layer GI2 including silicon nitride (e.g., Si₃N₄ or SiNx) have the same etch rate.

Therefore, when the process is performed at the second temperature Tm2, the first to fifth insulating layers GI1, GI2, GI3, GI4, and GI5 may have the same etch rate, and thus may be formed in the shape illustrated in the display device 10s of FIG. 11.

That is, when the dry cleaning process is performed at the second temperature Tm2 in the process of fabricating the display device 10, the side surfaces ss11, ss21, ss31, ss41, and ss51 of the first to fifth insulating layers GI1, GI2, GI3, GI4, and GI5 may be disposed on the same line. The redundant descriptions will be omitted.

In addition, as illustrated in the graph, when the dry cleaning process is performed at the first temperature Tm1 and a temperature range between the first temperature Tm1 and the second temperature Tm2, the etch rate of silicon nitride (e.g., Si₃N₄ or SiNx) may be higher than the etch rate of silicon oxide (e.g., SiO₂ or SiOx).

This may mean that when the process is performed at the first temperature Tm1 and the temperature range between the first temperature Tm1 and the second temperature Tm2, the first insulating layer GI1 has a lower etch rate than that of the second insulating layer GI2.

Therefore, when the process is performed at the first temperature Tm1 and the temperature range between the first temperature Tm1 and the second temperature Tm2, the first to fifth insulating layers GI1, GI2, GI3, GI4, and GI5 may be formed in the shapes of the display device 10 illustrated in FIG. 8 and the display device 10a illustrated in FIG. 10.

That is, when the dry cleaning process is performed at the first temperature Tm1 and the temperature range between the first temperature Tm1 and the second temperature Tm2 in the process of fabricating the display device 10, the side surface of the first insulating layer GI1 and the side surface of the fifth insulating layer GI5 may protrude further a direction toward the hole HOL than the side surface of the second insulating layer GI2 and the side surface of the third insulating layer GI3.

The display device 10 and the display device 10a in an embodiment may be easily fabricated as including a relatively wide range of process temperatures T.

In addition, as illustrated in the graph, when the dry cleaning process is performed at the third temperature Tm3 and a temperature range between the third temperature Tm3 and the second temperature Tm2, the etch rate of silicon nitride (e.g., Si₃N₄ or SiNx) may be lower than the etch rate of silicon oxide (e.g., SiO₂ or SiOx).

This may mean that when the process is performed at the third temperature Tm3 and the temperature range between the third temperature Tm3 and the second temperature Tm2, the first insulating layer GI1 has a higher etch rate than that of the second insulating layer GI2.

Therefore, when the process is performed at the third temperature Tm3 and the temperature range between the third temperature Tm3 and the second temperature Tm2, the first insulating layer GI1 and the second insulating layer GI2 may have an undercut shape, as illustrated in the display device EX according to the comparative embodiment of FIG. 9.

As described above, when the undercut is formed between the first insulating layer GI1 and the second insulating layer GI2, a contact defect of the conductive pattern may occur during the process of forming a subsequent conductive pattern. Therefore, the dry cleaning process in an embodiment may be performed at at least one temperature in the range from the second temperature Tm2 or higher to the first temperature Tm1 or lower.

As a result, a first contact hole CH1 and a second contact hole CH2 may be defined.

In the process, the first contact hole CH1 may be defined in a portion overlapping the first drain region D1 of the first active layer ACT1, and the second contact hole CH2 may be defined in a portion overlapping the first source region S1 of the first active layer ACT1. The recessed area rr1 of the first active layer ACT1 may be defined in a portion overlapping the first contact hole CH1 and the second contact hole CH2.

In the process, a width Wch1 of the first contact hole CH1 may be 2.0 micrometers or less, a depth Dch1 thereof may be 1.2 micrometers or more, and an aspect ratio (“AR”) obtained by dividing the depth Dch1 of the first contact hole CH1 by the width Wch1 of the first contact hole CH1 may be 0.6 or greater. In addition, a width Wch2 of the second contact hole CH2 may be 2.0 micrometers or less, a depth Dch2 thereof may be 1.2 micrometers or more, and an aspect ratio (“AR”) of the second contact hole CH2 may be 0.6 or greater.

For convenience of explanation, although FIG. 19 illustrates the structure of the first to fifth insulating layers GI1, GI2, GI3, GI4, and GI5 included in the display device 10 of FIG. 8, the shapes of the first to fifth insulating layers GI1, GI2, GI3, GI4, and GI5 may include both the shapes included in the display device 10a of FIG. 10 and the shapes included in the display device 10s of FIG. 11. Other redundant descriptions will be omitted.

In the process, the first contact hole CH1 and the second contact hole CH2 may include a lower area Lch and an upper area Uch. The lower area Lch may be an area relatively close to the substrate SUB, and the upper area Uch may be an area relatively far from the substrate SUB.

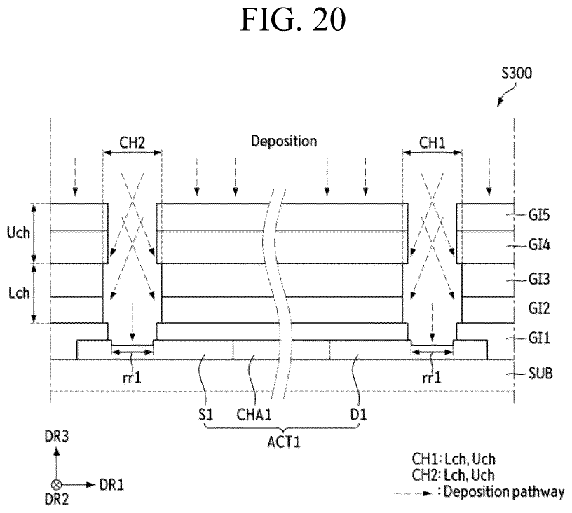

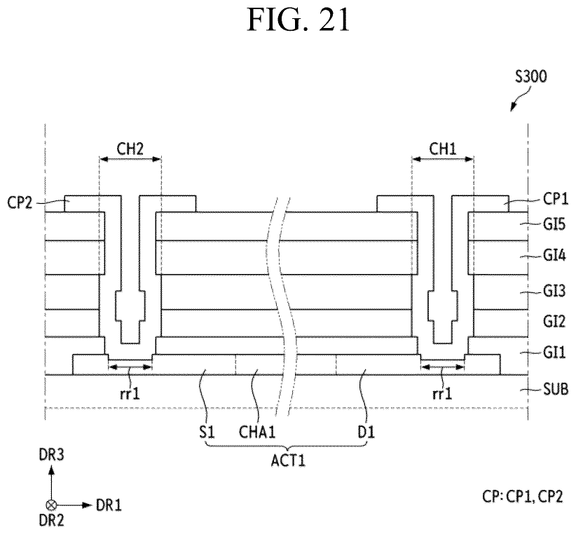

FIGS. 20 and 21 are cross-sectional views illustrating operation S400 of FIG. 13.

The operation (S400) of forming a conductive pattern in a portion overlapping the contact hole will be described with reference to FIGS. 20 and 21.

First, a conductive pattern CP is deposited on the first active layer ACT1 and the first to fifth insulating layers GI1, GI2, GI3, GI4, and GI5.

In the process, a deposition pathway of a material forming the conductive pattern CP may be performed not only in a vertical direction but also in an inclined direction with respect to the substrate SUB. Therefore, the material forming the conductive pattern CP may also be formed inside the first contact hole CH1 and the second contact hole CH2.

However, since the contact hole in an embodiment has a narrow and deep shape, the step coverage characteristics of the material forming the conductive pattern CP may be relatively lower in the lower area Lch than that in the upper area Uch of the first contact hole CH1 and the second contact hole CH2.

Therefore, the display device 10 in an embodiment may structurally increase the limitation of the step coverage characteristics of the conductive pattern by forming the first insulating layer GI1 to protrude further than the second insulating layer GI2 in the portion overlapping the lower area Lch of the first contact hole CH1 and the second contact hole CH2, or forming the side surface of the first insulating layer GI1 and the side surface of the second insulating layer GI2 so as to be disposed on the same line. The redundant descriptions will be omitted.

Although not illustrated in the drawing, a patterning process of the conductive pattern CP is performed following the deposition process. The process may remove a portion of the material forming the conductive pattern CP entirely deposited using a photoresist or mask.

In the process, the material forming the conductive pattern CP may be formed in the shape of a first conductive pattern CP1 and a second conductive pattern CP2. The first conductive pattern CP1 may be formed in a portion overlapping the first contact hole CH1, and the second conductive pattern CP2 may be formed in a portion overlapping the second contact hole CH2.

The first conductive pattern CP1 and the second conductive pattern CP2 may contact and cover the recessed area rr1 of the first active layer ACT1, and may contact and cover the first to fifth insulating layers GI1, GI2, GI3, GI4, and GI5 in the portions overlapping the first contact hole CH1 and the second contact hole CH2 by extending therefrom.

As a result, the first conductive pattern CP1 and the second conductive pattern CP2 of FIG. 7 may be formed.

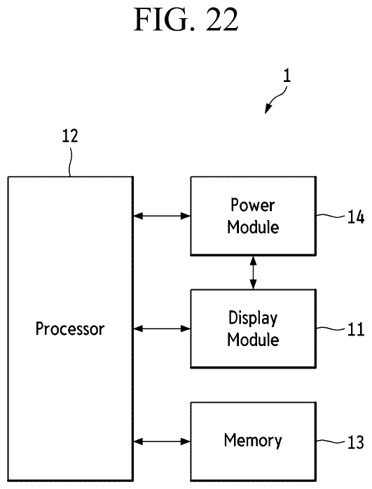

FIG. 22 is a block diagram of an embodiment of an electronic device.

Referring to FIG. 22 in addition to FIGS. 1 to 21, the display devices 10, 30, and 50 in the embodiments may be applied to various electronic devices 1. The electronic device 1 in an embodiment may include the display device 10 described above, and may further include a module or device having additional functions in addition to the display device 10.

The electronic device 1 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

Data information desired for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power desired for an operation of the electronic device 1.

At least one of the components of the electronic device 1 described above may be included in the display device according to the above-described embodiments. In addition, some of the individual modules functionally included within one module may be included within the display device, while others may be provided separately from the display device. In an embodiment, the display device includes the display module 11, and the processor 12, the memory 13 and the power module 14 may be provided in the form of other devices within the electronic device 1 other than the display device, for example.

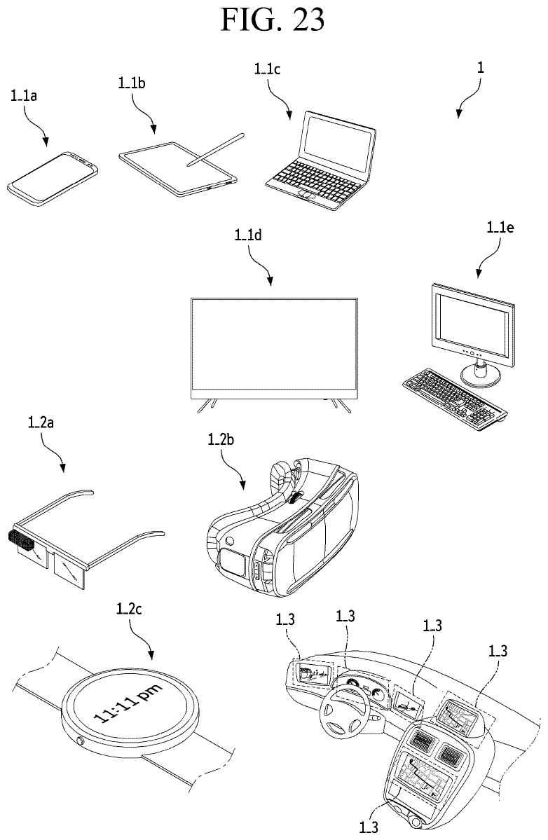

FIG. 23 illustrates schematic diagrams of electronic devices according to various embodiments.

Referring to FIG. 23, various electronic devices 1 to which the display device 10 in the embodiments is applied may include not only an image display electronic device such as a smart phone 1_1a, a tablet PC 1_1b, a laptop 1_1c, a television (“TV”) 1_1d, and a desk monitor 1_1e, but also a wearable electronic device including a display module such as a smart glasses 1_2a, a head mounted display 1_2b, a smart watch 1_2c, or the like, and a vehicle electronic device 1_3 including a display module such as a center information display (“CID”), a room mirror display, etc., disposed on a vehicle's instrument panel, center fascia, or dashboard.

However, the effects of the disclosure are not restricted to the one set forth herein. The above and other effects of the disclosure will become more apparent to one of daily skill in the art to which the disclosure pertains by referencing the claims.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a substrate including a semiconductor layer;
a plurality of insulating layers which defines a contact hole penetrating through the plurality of insulating layers and exposes the semiconductor layer, the plurality of insulating layers including:
a first insulating layer in contact with the semiconductor layer; and
a second insulating layer disposed in contact with the first insulating layer; and
a conductive pattern covering the semiconductor layer and the plurality of insulating layers in a portion overlapping the contact hole,
wherein a recessed area which is recessed in a direction toward the substrate in the portion overlapping the contact hole is defined in the semiconductor layer,
the first insulating layer and the second insulating layer include different materials from each other, and
the recessed area of the semiconductor layer and the first insulating layer have a step-shaped level difference.

2. The display device of claim 1, wherein the first insulating layer protrudes further in a direction toward the contact hole than the second insulating layer, and
the recessed area of the semiconductor layer, the first insulating layer, and the second insulating layer have a step-shaped level difference.

3. The display device of claim 2, wherein the first insulating layer defines a first opening in the portion overlapping the contact hole,
the second insulating layer defines a second opening in the portion overlapping the contact hole, and
a width of the first opening and a width of the second opening are different from each other.

4. The display device of claim 3, wherein the width of the first opening is smaller than the width of the second opening.

5. The display device of claim 4, wherein a difference between the width of the first opening and the width of the second opening is 10 angstroms or more and 300 angstroms or less.

6. The display device of claim 1, wherein an aspect ratio of the contact hole is defined as a value obtained by dividing a depth of the contact hole by a width of the contact hole, and
the aspect ratio of the contact hole is 0.6 or greater.

7. The display device of claim 6, wherein the depth of the contact hole is 1.2 micrometers or more, and the width of the contact hole is 2.0 micrometers or less.

8. The display device of claim 1, wherein the recessed area of the semiconductor layer does not overlap the plurality of insulating layers in a direction perpendicular to the substrate.

9. The display device of claim 8, wherein a width of the recessed area of the semiconductor layer in a direction parallel to the substrate is smaller than a width of the contact hole.

10. The display device of claim 1, wherein the semiconductor layer includes polysilicon.

11. The display device of claim 1, wherein a side surface of the first insulating layer facing the contact hole is disposed on the same line as a side surface of the second insulating layer facing the contact hole.

12. The display device of claim 1, wherein the conductive pattern contacts and covers the recessed area of the semiconductor layer, the first insulating layer, and the second insulating layer in the portion overlapping the contact hole.

13. A method for fabricating a display device, the method comprising:
forming a plurality of insulating layers on a substrate including a semiconductor layer;
removing a portion of the plurality of insulating layers by performing a dry etching process;
defining a contact hole by performing a dry cleaning process; and
forming a conductive pattern in a portion overlapping the contact hole,
wherein the plurality of insulating layers include a first insulating layer in contact with the semiconductor layer and a second insulating layer in contact with the first insulating layer and including a different material from the first insulating layer.

14. The method of claim 13, wherein in the removing the portion of the plurality of insulating layers by performing the dry etching process,
the semiconductor layer defines a recessed area which is recessed in a direction toward the substrate.

15. The method of claim 14, wherein in the defining the contact hole by performing the dry cleaning process,
the recessed area of the semiconductor layer, the first insulating layer, and the second insulating layer include a step-shaped level difference.

16. An electronic device comprising:
a display device including a substrate including a semiconductor layer, the display device including:
a plurality of insulating layers defining a contact hole which penetrates through the plurality of insulating layers and exposes the semiconductor layer, the plurality of insulating layers including:
a first insulating layer in contact with the semiconductor layer; and
a second insulating layer disposed in contact with the first insulating layer; and
a conductive pattern covering the semiconductor layer and the plurality of insulating layers in a portion overlapping the contact hole,
a display device accommodating portion in which the display device is accommodated; and
an optical member enlarging a display image of the display device or converting a light path,
wherein the semiconductor layer includes a recessed area which is recessed in a direction toward the substrate in the portion overlapping the contact hole,
the first insulating layer and the second insulating layer include different materials from each other, and
the recessed area of the semiconductor layer and the first insulating layer have a step-shaped level difference.

17. The electronic device of claim 16, wherein the first insulating layer protrudes further in a direction toward the contact hole than the second insulating layer, and
the recessed area of the semiconductor layer, the first insulating layer, and the second insulating layer have a step-shaped level difference.

18. The electronic device of claim 17, wherein the first insulating layer defines a first opening in the portion overlapping the contact hole,
the second insulating layer defines a second opening in the portion overlapping the contact hole, and
the width of the first opening is smaller than the width of the second opening.

19. The electronic device of claim 18, wherein a difference between the width of the first opening and the width of the second opening is 10 angstroms or more and 300 angstroms or less.

20. The electronic device of claim 16, wherein an aspect ratio of the contact hole is defined as a value obtained by dividing a depth of the contact hole by a width of the contact hole, and
the aspect ratio of the contact hole is 0.6 or greater.
